(19) United States
(12) Patent Application Publication
(10) Pub. No.: US 2002/0013007 A1
(43) Pub. Date: Jan. 31, 2002

(54) Semiconductor wafer polishing end point detection method and apparatus

(75) Inventors: Koichi Hasegawa, Tokyo (JP); Hideo Mitsuhashi, Tokyo (JP); Katsuhisa Ookawa, Tokyo (JP)

Correspondence Address: SUGHRUE, MION, ZINN, MACPEAK & SEAS, 2100 Pennsylvania Avenue, N.W., Washington, DC, 20037, US

(73) Assignee: NEC CORPORATION

(21) Appl. No.: 09/879,144

(22) Filed: Jun. 13, 2001

(30) Foreign Application Priority Data
Jun. 16, 2000 (JP) 182199/2000

(51) Int. Cl. H01L 21/00; C23F 1/02

(52) U.S. Cl. 438/8; 156/345

(57) ABSTRACT

In a semiconductor wafer polishing end point detection method, a polishing progress state distribution on the surface of a semiconductor wafer by chemical and mechanical polishing in forming a metal wire is measured by using one or more measurement systems. The end point of polishing is detected on the basis of a measurement result, thereby obtaining an optimal polishing result. A semiconductor wafer polishing end point detection apparatus is also disclosed.

### BACKGROUND OF THE INVENTION

The present invention relates to a semiconductor wafer polishing end point detection method and apparatus for detecting the end point of CMP (Chemical and Mechanical Polishing) for various thin films formed on the surface of a semiconductor wafer.

As the interconnection width decreases, the influence of dishing in which an interconnection center is excessively shaved to dish the center of the interconnection portion cannot be ignored in polishing a semiconductor wafer by a CMP apparatus. Further, as wires concentrate, the influence of erosion in which the central portion of a dense interconnection area is excessively shaved to decrease the sectional area of the excessively shaved wire cannot be ignored. To prevent this, a polishing method of polishing a plurality of films in a plurality of polishing steps by using an efficient polishing solution for each film is adopted. Japanese Patent Laid-Open No. 11-345791 discloses a method of detecting the CMP end point of a semiconductor wafer.

The prior art disclosed in this reference detects by one polishing cycle the end point of polishing for all thin films such as a metal film, barrier film, and insulating film formed on a wafer surface. This prior art cannot detect the end point of polishing of a wafer after removal of a metal film by divisional polishing.

Generally in a semiconductor device, a film called a barrier film for preventing diffusion of a metal film is formed between the uppermost metal film and the lowermost insulating film. The end point of polishing of a wafer after removal of the metal film cannot be detected. Polishing nonuniformity may generate a portion where polishing is completed and a portion where polishing is not completed. If an unpolished portion exists, it must be polished again after an inspection in the subsequent step. The existence of an unpolished portion owing to polishing nonuniformity poses problems. Polishing nonuniformity may occur upon removing a metal film. There is no means for monitoring the degree of polishing nonuniformity, and polishing nonuniformity must be checked in the subsequent step.

### SUMMARY OF THE INVENTION

It is an object of the present invention to provide a semiconductor wafer polishing end point detection method and apparatus for detecting the end point of polishing for removing a barrier film on an insulating film from a wafer after a metal film is removed.

It is another object of the present invention to provide a semiconductor wafer polishing end point detection method and apparatus capable of eliminating polishing nonuniformity and obtaining an optimal polishing result.

To achieve the above objects, according to the present invention, there is provided a semiconductor wafer polishing end point detection method comprising the steps of measuring, by using at least one measurement system, a polishing progress state distribution on a surface of a semiconductor wafer by chemical and mechanical polishing in forming a metal interconnection, and detecting an end point of polishing on the basis of a measurement result, thereby obtaining an optimal polishing result.

### BRIEF DESCRIPTION OF THE DRAWINGS

FIG. 1 is a schematic view showing a semiconductor wafer polishing end point detection apparatus according to the first embodiment of the present invention;

FIG. 2 is a sectional view showing main part of the surface of a semiconductor wafer shown in FIG. 1;

FIG. 3 is a view showing a polishing solution removal device disposed on the target polishing surface of the semiconductor wafer shown in FIG. 1;

FIG. 4 is a block diagram showing an end point detection device shown in FIG. 1;

FIG. 5A is a graph showing temporal changes in average data along with polishing progress;

FIG. 5B is a graph showing temporal changes in inclination data during polishing;

FIG. 6 is a flow chart showing an algorithm A executed by an arithmetic unit shown in FIG. 4;

FIG. 7 is a schematic view showing a semiconductor wafer polishing end point detection apparatus according to the second embodiment of the present invention;

FIG. 8 is a block diagram showing an end point detection device according to the second embodiment shown in FIG. 7;

FIG. 9A is a graph showing temporal changes in two average data during polishing;

FIG. 9B is a graph showing temporal changes in two corrected average data during polishing;

FIG. 9C is a graph showing temporal changes in difference inclination data of two corrected average data during polishing;

FIG. 10 is a flow chart showing an algorithm B executed by an arithmetic unit shown in FIG. 8;

FIG. 11 is a block diagram showing an end point detection device according to the third embodiment of the present invention;

FIG. 12A is a graph showing changes in average data along with polishing progress;

FIG. 12B is a graph showing temporal changes in inclination data during polishing;

FIG. 13 is a flow chart showing an algorithm C executed by an arithmetic unit shown in FIG. 11;

FIG. 14 is a flow chart showing the operations of an average calculation unit and inclination calculation unit according to the fourth embodiment of the present invention;

FIG. 15 is a schematic view showing a semiconductor wafer polishing end point detection apparatus according to the fifth embodiment of the present invention;

FIG. 16 is a block diagram showing an end point detection device shown in FIG. 15;

FIG. 17 is a flow chart showing an algorithm D executed by an arithmetic unit shown in FIG. 16;

FIG. 18 is a flow chart showing the operation of a semiconductor wafer polishing end point detection apparatus according to the seventh embodiment of the present invention;

FIG. 19 is a waveform chart showing polishing of a wafer having only an insulating film according to the eighth embodiment of the present invention; and

FIG. 20 is a block diagram showing a semiconductor wafer polishing end point detection apparatus according to the ninth embodiment of the present invention.

### DESCRIPTION OF THE PREFERRED EMBODIMENTS

The present invention will be described in detail below with reference to the accompanying drawings.

(First Embodiment)

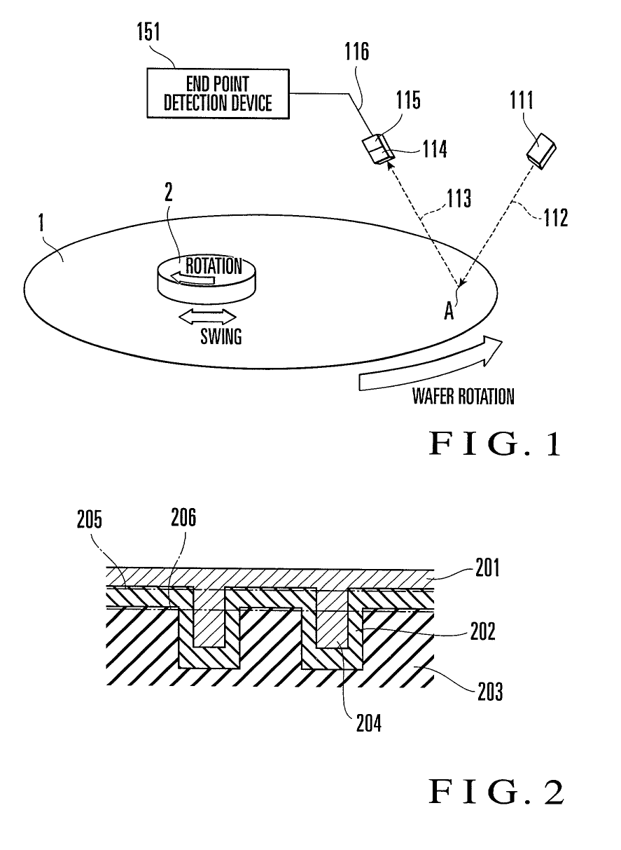

FIG. 1 shows a semiconductor wafer polishing end point detection apparatus according to the first embodiment of the present invention. The semiconductor wafer polishing end point detection apparatus of the first embodiment is constituted by adding a measurement system to a semiconductor wafer polishing apparatus. The semiconductor wafer polishing apparatus shown in FIG. 1 comprises a wafer 1 supported so as to sufficiently stand the polishing pressure while being rotated within a horizontal plane, and a polisher 2 which comes into contact with the wafer 1 at a predetermined pressure and swings radially along the wafer 1 while rotating.

The measurement system comprises a light source 111 serving as a light source for emitting inspection light 112 having a predetermined wavelength that irradiates the wafer 1 with a predetermined diameter and angle, a light-receiving element 114 which is interposed on the optical path of reflected light 113 obtained by regularly reflecting by the wafer 1 the inspection light 112 emitted by the light source 111, and receives the reflected light 113 to measure the reflected light quantity, a light-receiving element amplifier 115 for outputting as a reflected light quantity signal 116 the reflected light quantity of the reflected light 113 converged on the light-receiving surface of the light-receiving element 114, and an end point detection device 151 for detecting the end point of polishing.

As shown in FIG. 4, the end point detection device 151 is comprised of an average calculation unit 411 for calculating the average of one wafer rotation on the basis of the input reflected light quantity signal 116 and storing/outputting the average as average data 412, an inclination calculation unit 413 for calculating the average inclination of the average data 412 at a plurality of points and storing/outputting the average inclination as inclination data 414, and an arithmetic unit 416 for detecting the end point of polishing from a change in the inclination data 414 over time, and outputting the end point of polishing as an end point detection signal 415.

FIG. 2 shows the sectional shape of the surface of the semiconductor wafer 1 to be polished. In FIG. 2, a metal film 201 is formed as the uppermost layer on the surface of the semiconductor wafer so as to cover an insulating film 203. A barrier film 202 for preventing diffusion of the metal film is formed between the uppermost metal film 201 and lower insulating film 203.

Formation of interconnection portions 204 by polishing the semiconductor wafer by a CMP apparatus and leaving the metal film in grooves causes the phenomenon called dishing in which the center of the interconnection portion 204 is excessively shaved to dish it as the width of the interconnection portion 204 decreases. This also causes the phenomenon called erosion in which the central portion of a dense interconnection area is excessively shaved to decrease the sectional area of the excessively shaved interconnection portion 204 as the interconnection portions 204 concentrate. The influence of these phenomena cannot be ignored, so that divisional polishing is performed in several steps by using a polishing solution for efficiently polishing a specific film in order to suppress generation of the phenomena, as described above.

In the example shown in FIG. 2, a first polishing end point 205 is detected by using a polishing solution which efficiently polishes the metal film 201 by first polishing and hardly polishes the barrier film 202. Second polishing uses a polishing solution which efficiently polishes the barrier film 202 and hardly polishes the metal film 201. During second polishing, the influence of dishing and erosion is substantially eliminated, the exposed barrier film 202 except for the interconnection portion 204 which is formed from the metal film 201 and left after the first polishing end point 205 is polished away, and a polishing end point 206 is detected.

In divisional polishing, it is important that no barrier film 202 remains on the insulating film 203 due to insufficient polishing except for the grooves of the interconnection portions 204 at the polishing end point 206 immediately before the next step, and that the insulating film 203 is not excessively polished. The present invention precisely detects the polishing end point 206 of the wafer from which the metal film 201 is removed.

In the measurement system shown in FIG. 1, the inspection light 112 having a predetermined wavelength that is emitted by the light source 111 irradiates an irradiation position A on the wafer 1 with a predetermined diameter, and the flux of the light 113 regularly reflected at the irradiation position A converges on the light-receiving surface of the light-receiving element 114. Output light from a semiconductor laser as the light source 111 is collimated by a collimator lens (not shown), and shaped into light having a predetermined diameter smaller than the light-receiving surface of the light-receiving element 114 via a beam diameter conversion optical system or by transmitting the light beam through a mask having an aperture with a predetermined diameter. At this time, the diameter is given a margin on the small-diameter side so as to allow almost the whole light to enter the light-receiving element even if light slightly fluctuates owing to waves on the surface of the polishing solution on the wafer surface and the diameter slightly varies. The inspection light 112 is irradiated at a predetermined angle much smaller than the total reflection angle so as to suppress the influence of variations in reflection angle or suppress reflection on the surface of the polishing solution.

The light source 111 can be a general laser such as a solid-state laser or gas laser other than a semiconductor laser. A laser capable of emitting parallel light does not require any collimator lens. If necessary, the optical path of light is designed by using a reflecting mirror or the like so as not to interrupt swings or polishing operation of the polisher.

The wavelength of output light from the light source 111 is selected such that the reflectance is as high as possible on the metal film 201 and as low as possible on the barrier film 202 and lower film. For example, when the metal film is made of copper, the spectral reflectance exceeds 90% for a wavelength of 600 nm to 10 μm, and light within this wavelength range is used. Further, a wavelength in a visible light range of 600 nm or more is preferably used because the barrier film and underlying film are lower in reflectance than the metal film 201, the optical path can be easily adjusted, and thermal radiation occurs at an infrared wavelength. Also when the metal film 201 is made of another material such as aluminum, a wavelength lower on the barrier film 202 and underlying film than on the metal film is selected to increase the reflectance.

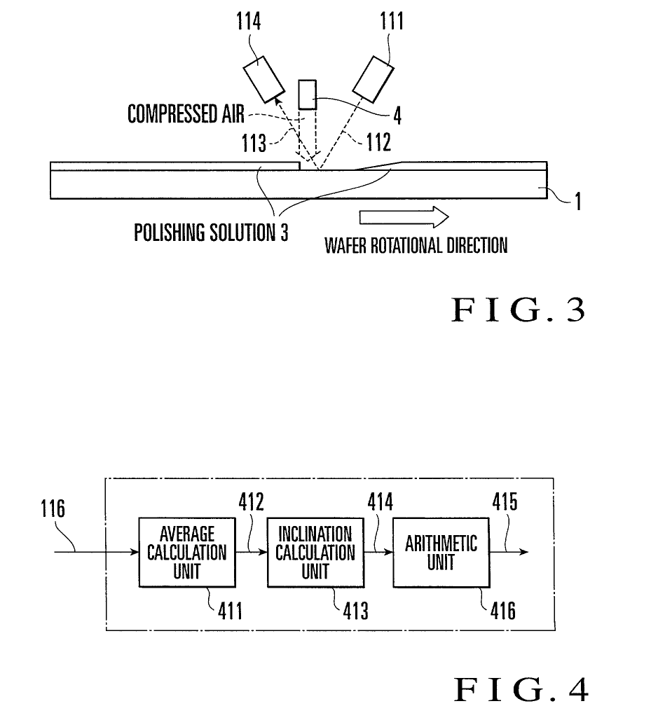

At the irradiation position A, as shown in FIG. 3, a polishing solution removal device 4 removes a polishing solution 3 to a degree not to greatly influence reflected light by waves generated on the surface of the polishing solution 3, so as not to obstruct regular reflection of the inspection light 112 and reflected light 113 on the wafer 1 due to the polishing solution 3 present on the polishing target surface of the wafer 1.

The polishing solution removal device 4 is constituted by, e.g., an air nozzle for spraying air focused on the irradiation position A on the wafer 1 and removing the polishing solution 3. The polishing solution 3 may be removed by using a substance which transmits inspection light, is in contact with the wafer so as to cover the irradiation position A, and does not damage the wafer even by rotation. Alternatively, the polishing solution 3 around the irradiation position A may be removed by a means such as an automobile wiper which is disposed upstream in the wafer rotational direction with a width enough to cover the width of the irradiation position A and uses a substance that is in contact with the wafer but does not damage it even by rotation.

It is important that the polishing solution 3 does not obstruct changes in the reflected light quantity signal 116 along with the polishing progress of the wafer 1. Changes in polishing progress suffice to be measured by the reflected light quantity signal 116. Note that the polishing solution removal device 4 can be omitted unless the polishing solution 3 greatly influences measurement of the reflectance on the surface of the wafer 1.

Since a given metal such as copper oxidizes under the influence of oxygen in air, the polishing solution 3 is not completely removed but is left thin on the surface. As described above, a semiconductor laser beam is collimated into parallel light via the collimator lens. However, light may not be parallel light as far as almost the whole reflected light enters the light-receiving surface, and may be convergent or divergent light. The wafer 1 rotates during polishing operation, sparse and dense patterns are aligned on the wafer 1, and thus the reflected light quantity signal 116 changes mainly depending on the density of the interconnection portions 204 along with rotation of the wafer 1. The reflected light quantity signal 116 is input as a signal having periodic changes to the end point detection device 151.

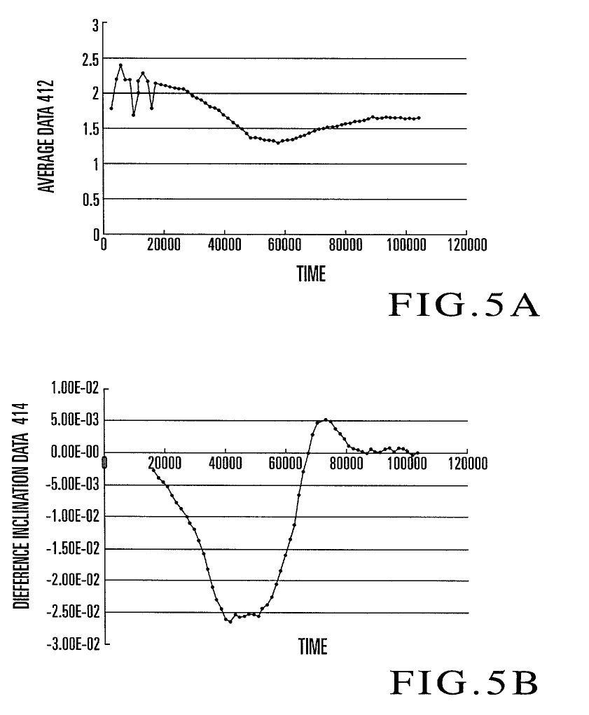

The operation of the end point detection device 151 shown in FIG. 4 will be explained with reference to FIGS. 5A and 5B.

Polishing progress appears as signal changes from which the periodic changes of the reflected light quantity signal 116 are removed. The average calculation unit 411 receives reflected light quantity signals 116 at a predetermined interval, averages the reflected light quantity signals 116 obtained during one rotation of the wafer 1 as the average data 412, and stores the average data 412 with the lapse of time every rotation. At this time, average data may be calculated by averaging the reflected light quantity signals 116 every natural number multiple of one rotation or averaging the reflected light quantity signals 116 within a predetermined time during one rotation every natural number multiple of one rotation.

The graph of FIG. 5A shows changes in average data along with polishing progress when the metal film 201 is removed and the wafer 1 having the barrier film 202 is polished. The average data exhibits the following characteristic changes (1) to (4) along with polishing progress.

(1) A relatively large change appears at the beginning of polishing.

(2) The reflected light quantity decreases.

(3) The reflected light quantity increases.

(4) The reflected light quantity hardly changes and stabilizes.

In (1), the relatively large change appears at the beginning of polishing until the wafer 1 and polisher 2 adapt to each other, and is a change irrespective of polishing progress in the initial unstable region. In (2), the decrease in reflected light quantity is a change as the barrier film becomes thinner along with polishing progress. This occurs because the reflectance of the film below the barrier film 202 and that of the barrier film including the interference effect are lower than the reflectance of the metal film 201 and the ratio of the influence of the barrier film 202 on the wafer surface decreases along with polishing progress.

In (3), the reflected light quantity increases because the barrier film 202 becomes thin and the reflectance is influenced by reflection on the insulating film 203 below the barrier film 202, the lower interconnection pattern of the wafer 1 bearing a multilayered interconnection pattern, or a layer having a higher reflectance than that of the barrier film 202 including the interference effect. The reflectance is determined not only by the influence of the material but also by interference caused by the film thickness.

In (4), the reflected light quantity stabilizes after the reflected light quantity is determined by reflection on the metal film 201 left in the groove of the interconnection portion after removal of the barrier film 202 and reflection on the underlying film including the insulating film 203, and the areas of the metal portion and insulating film portion do not change. During the stable period, the metal film 201 which forms an interconnection portion maintains a thickness enough to reflect the inspection light 112, and the interference effect is not greatly changed by a change in the thickness of the insulating film 203. After this period, the reflected light quantity changes again.

The present invention detects the end point of polishing in order not to excessively polish the interconnection portion, and does not consider the reflected light quantity after the stable period because polishing ends during the stable period.

The relatively large change appears at the beginning of polishing until the wafer 1 and polisher 2 adapt to each other. Even after the average calculation unit 411 removes periodic changes, this change exhibits a difference from polishing progress, causing a determination error.

To prevent erroneous detection of the end point of polishing caused by a change different from polishing progress at the beginning of polishing, the average data 412 is ignored a predetermined time after the start of polishing. Even if the unstable element of the average data 412 at the beginning of polishing can be removed, the average data 412 still contains a noise component due to nonuniformity of polishing progress radially along the wafer, measurement precision nonuniformity, or mixture of noise, and the average data 412 must be satisfactorily smoothed. For this purpose, the inclination calculation unit 413 calculates the average inclination of a plurality of data back to the past by a predetermined number of data containing the current value among the average data 412, and outputs the average inclination as the inclination data 414.

The graph of FIG. 5B shows changes in the inclination data 414. The average inclination may be calculated by using the least squares method of a plurality of data or by connecting the average of a plurality of data to the average of a plurality of data back to the past by a predetermined number of data. The temporal change of average data in FIG. 5A and that of inclination data in FIG. 5B have the same time axis. The comparison between these graphs represents removal of any noise component from changes in reflected light quantity in FIG. 5A.

The arithmetic unit 416 determines the final end point of polishing on the basis of the inclination data 414, and notifies the polisher of the end point of polishing by the end point detection signal 415. Then, the polisher ends polishing.

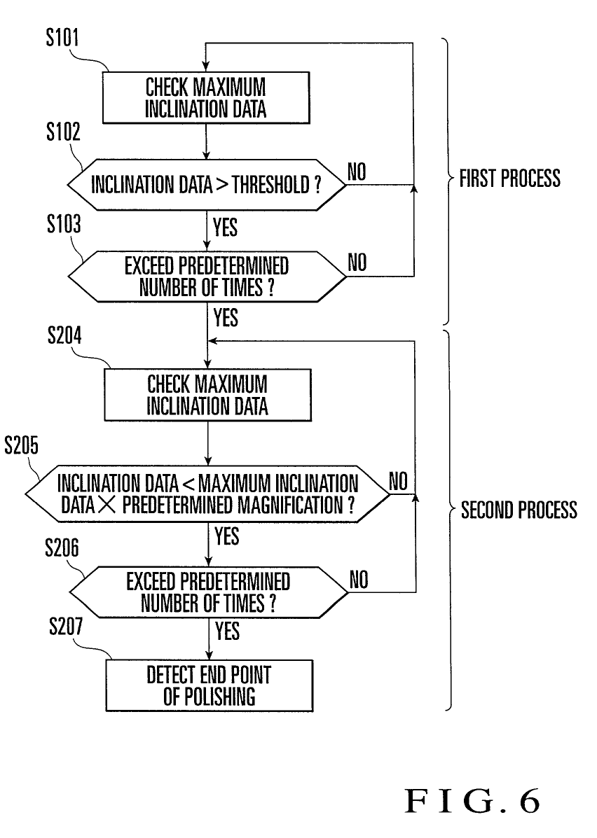

A polishing end point determination algorithm A in the arithmetic unit 416 will be explained with reference to the flow chart shown in FIG. 6.

As shown in FIG. 5A, the arithmetic unit 416 performs the first process of detecting an increase in the average data 412. In the first process, the arithmetic unit 416 checks whether the inclination data 414 is a positive value, in order to detect whether the average data 412 increases, i.e., the inclination changes from “negative” to “positive” (step S101). In this case, the arithmetic unit 416 should not erroneously recognize that the inclination data becomes 0 instantaneously or temporarily due to abrupt noise or that the inclination data becomes 0 because the reflected light quantity does not increase but stabilizes. For this reason, instead of simply determining whether the inclination data exceeds 0 from a negative value, a threshold around 0 is set in advance, and the inclination is compared with the threshold to check whether the inclination data exceeds the threshold (step S102).

The arithmetic unit 416 checks whether the inclination data has exceeded the threshold successively a plurality of number of times (step S103). If Yes in step S103, the first process ends. In step S101 which constitutes a conditional loop in the first process, the inclination data is confirmed, and if it is maximum, this value is held as maximum inclination data.

In the second process, the arithmetic unit 416 detects stabilization of the average data after the increase in the average data. Similar to the first process, the arithmetic unit 416 checks the inclination data in step S204, and if it is maximum, holds this value as maximum inclination data. In step S205, the arithmetic unit 416 determines whether the inclination data satisfies “inclination data<maximum inclination data×predetermined magnification”, and compares the inclination data with the product of the maximum inclination data and a predetermined magnification. In step S206, the arithmetic unit 416 checks whether the condition in step S205 is satisfied a predetermined number of times. If Yes in step S206, the arithmetic unit 416 detects the end point of polishing (step S207).

The inclination data 414 is compared with the product of the maximum inclination data and the predetermined magnification because of the following reason. When the average data slightly increases, the inclination data gradually changes around 0, and the maximum inclination data value is relatively small. By using a threshold obtained by multiplying the maximum inclination data by the predetermined magnification, the threshold can be set around the end point of polishing, i.e., inclination data of 0.

To the contrary, when the average data greatly increases, the inclination data steeply changes, and the maximum inclination data is relatively large. By using a threshold obtained by multiplying the maximum inclination data by the predetermined magnification, the threshold can cope with the steep change, resulting in high polishing end point detection precision. Such a threshold can cope with a case wherein a signal becomes smaller with a constant S/N and the use of a determination value with a constant inclination decreases the detection precision, e.g., a case wherein the light intensity of the light source 111 of the inspection light 112 decreases in a long term due to deterioration or the like.

(Second Embodiment)

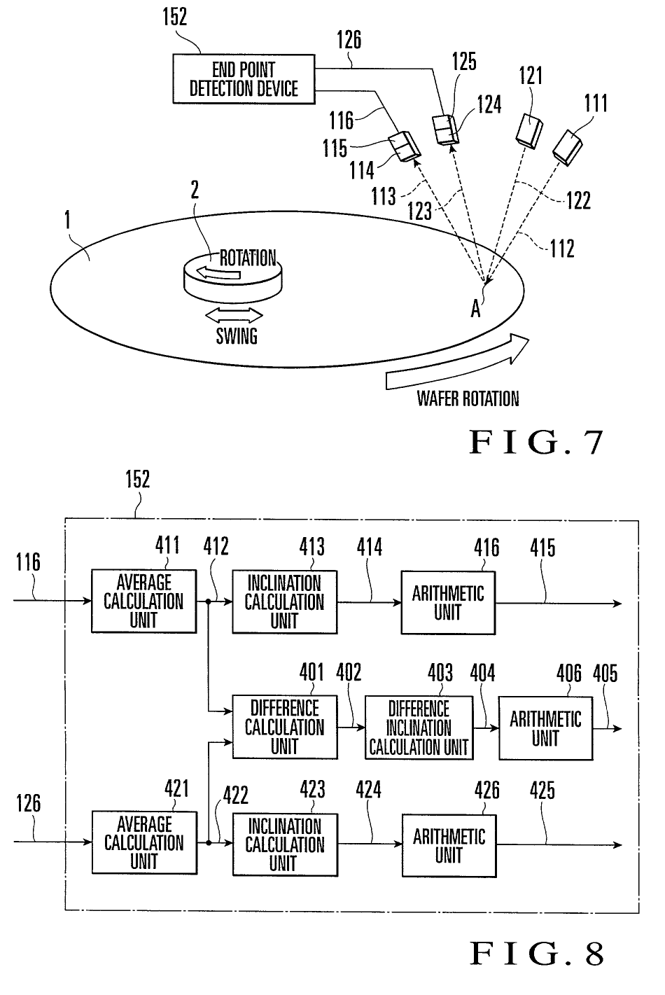

FIG. 7 shows a semiconductor wafer polishing end point detection apparatus according to the second embodiment of the present invention.

The apparatus shown in FIG. 7 includes all the building components of the apparatus shown in FIG. 1, and is additionally equipped with a second measurement system for irradiating the irradiation position A with the same diameter at a predetermined irradiation angle and wavelength different from those of the measurement system shown in FIG. 1 (measurement system shown in FIG. 1 will be referred to as a first measurement system hereinafter).

The second measurement system comprises a light source 121 for irradiating the irradiation position A with emitting inspection light 122 at a wavelength different from that of inspection light 112 of the first measurement system, the same diameter, and a different irradiation angle or the same irradiation angle by crossing optical paths on which optical systems can be interposed, a light-receiving element 124 which is interposed on the optical path of reflected light 123 obtained by regularly reflecting by a wafer 1 the inspection light 122 emitted by the light source 121, and receives the reflected light 123 to measure the reflected light quantity, and a light-receiving element amplifier 125 for outputting as a reflected light quantity signal 126 the reflected light quantity of the reflected light 123 converged on the light-receiving surface of the light-receiving element 124. The reflected light quantity signal 126 is output to an end point detection device 152.

The first and second measurement systems use different wavelengths in order to detect a difference in reflectance changes for each wavelength around the end point of polishing, and use different irradiation angles because no laser can be physically arranged so that the same irradiation position is irradiated. If optical systems such as small lasers or mirrors can be arranged, the optical paths may be crossed to irradiate the same irradiation position at the same irradiation angle. The first and second measurement systems irradiate the same irradiation position in order to detect the same place, and use the same diameter in order to prevent mixture of the state of another portion in a detection signal owing to different diameters.

As shown in FIG. 8, the end point detection device 152 comprises, in addition to an average calculation unit 411, inclination calculation unit 413, and arithmetic unit 416 in FIG. 4, an average calculation unit 421 for calculating the average of the reflected light quantity signals 126 output from the light-receiving element amplifier 125 and storing/outputting average data 422, an inclination calculation unit 423 for calculating the inclination of the average data 422 and storing/outputting inclination data 424, an arithmetic unit 426 for calculating an end point detection signal 425 on the basis of the inclination data 424, a difference calculation unit 401 for detecting the difference between the average data 412 and 422 and storing/outputting difference data 402, a difference inclination calculation unit 403 for calculating the inclination of the difference data 402 and storing/outputting difference inclination data 404, and an arithmetic unit 406 for calculating an end point detection signal 405 on the basis of the difference inclination data 404.

In the end point detection device 152 having this arrangement, polishing end point detection is performed for the average data 412 and 422 in accordance with the algorithm A, thereby obtaining the end point detection signals 415 and 425. At the same time, the difference calculation unit 401 calculates the difference data 402 representing the difference between the average data 412 and 422, and the difference inclination calculation unit 403 calculates the difference inclination data 404 representing the average inclination at a plurality of points. The arithmetic unit 406 detects the end point of polishing from temporal changes in the difference inclination data 404, and outputs the end point detection signal 405.

By inputting the average data 412 and 422 to the inclination calculation units 413 and 423 and also to the difference calculation unit 401, the arithmetic units 416, 426, and 406 can operate parallel to each other. Arbitrary one or two of the three arithmetic units can be selectively operated.

Similar to the first embodiment, a polishing solution is removed from the wafer 1 to be polished in FIG. 7 prior to polishing so as not to influence measurement.

The inspection light 122 having a predetermined wavelength that is emitted by the light source 121 which constitutes the second measurement system irradiates the irradiation position A on the wafer 1 with the same diameter as that of the inspection light 112 in the first measurement system. To allow almost the entire flux of the light 123 regularly reflected at the irradiation position A to enter the light-receiving surface of the light-receiving element 124, a semiconductor laser beam is collimated by a collimator lens (not shown), and shaped into a beam having a predetermined diameter smaller than that of the light-receiving surface of the light-receiving element 124 via a beam diameter conversion optical system or by transmitting the light beam through a mask having an aperture with a predetermined diameter. The light source can be a general laser as described in the first embodiment. A laser for emitting parallel light does not require any collimator lens.

As for the wavelength of the light source 121, a wavelength with which the reflectance is greatly different from that of a light source 111 which constitutes the first measurement system is selected in accordance with the type of metal material of a metal film 201 shown in FIG. 2. When the metal film 201 is made of copper, as described in the first embodiment, the spectral reflectance exceeds 90% for visible light having a wavelength of 600 nm or more, but is lower than 66% at a wavelength shorter than 550 nm. From this, the wavelength of the first measurement system is set to, e.g., 650 nm, and that of the second measurement system is set to, e.g., 500 nm. The wavelengths are similarly determined when the metal film 201 is made of another material.

With the light sources having different wavelengths, even the same film exhibits a different reflectance and reflected light quantity for each wavelength. Changes in reflected light quantity on a predetermined reference film and changes in reflected light quantity on the surface of the wafer 1 are checked on the basis of the fact that the spectral reflectance changes for each film owing to the wavelength difference. The end point of polishing is detected from changes in difference between the two reflected light quantities of the different wavelengths corrected to make the reflectance of the reference film coincide with that of the wafer 1.

The surface of the wafer 1 during polishing is not suited for a reference film serving as a reflectance reference because an interconnection pattern and insulating film 203 exist on the wafer surface, the reflected light quantity cannot be measured by only one specific wavelength, and the reflected light quantity changes due to interference upon a change in film thickness.

For this reason, the metal film 201 which is a single film and does not change by interference is used as a reference film. Two average data of different wavelengths measured when the metal film 201 is thick enough to be free from interference on the entire surface of the wafer 1 and the surface is smoothened by polishing are corrected to coincide with each other. This correction is called reference light quantity correction. By correcting the average data of respective wavelengths on the metal film 201 so as to coincide with each other, the average data greatly change owing to the difference in reflectance between the barrier film 202 and the insulating film 203 on the basis of the reflectance of the metal film 201 as a reference. The difference between the corrected average data which change depending on the barrier film 202 and insulating film 203 is calculated to detect the end point of polishing on the basis of the change.

More specifically, one of the average data 412 and 422 on the metal film 201 is set as a reference, and the other is multiplied by a given magnification to make the average data on the metal film 201 coincide with each other. However, a target wafer in the present invention is polished after the metal film 201 is removed, so average data serving as a reference on the metal film 201 cannot be measured. Prior to polishing, therefore, data is acquired from the wafer 1 before removal of the metal film, and saved. A case wherein the average data 412 on the metal film 201 in the first measurement system is set as a reference will be exemplified.

Normal polishing operation is performed on the wafer 1 before removal of the metal film 201, thereby obtaining the average data 412 and 422 before removal of the metal film 201. A large change at the beginning of polishing is ignored, similar to normal polishing operation, and then the average data 412 and 422 are kept acquired for a predetermined time. The averages for the predetermined time are calculated and saved as first and second reference reflected light quantities. The saved data are extracted immediately after the start of polishing, and a correction magnification used for reference light quantity correction is calculated. However, reference light quantity correction using only the reference reflected light quantities ignores variations in an emission output from the laser caused by the temperature or changes over time.

To prevent this, the laser output monitoring values of the first and second measurement systems are also measured at the same time as measurement of the reference reflected light quantities. The averages of the output monitoring values are calculated similarly to calculation of the reference reflected light quantities, and saved as first and second reference output values. When the wafer 1 from which the metal film 201 is removed is to be polished, laser output monitoring values obtained from the first and second measurement systems are measured at the start of polishing, the saved first and second reference reflected light quantities and the first and second reference output values are extracted as first and second current output values, and a correction magnification for reference light quantity correction is calculated by

Correction Magnification of First Measurement System=First Current Output Value/First Reference Output Value (1)

Correction Magnification of Second Measurement System={First Reference Reflected Light Quantity ×(First Current Output Value/First Reference Output Value)}/{Second Reference Reflected Light Quantity×(Second Current Output Value/Second Reference Output Value)} (2)

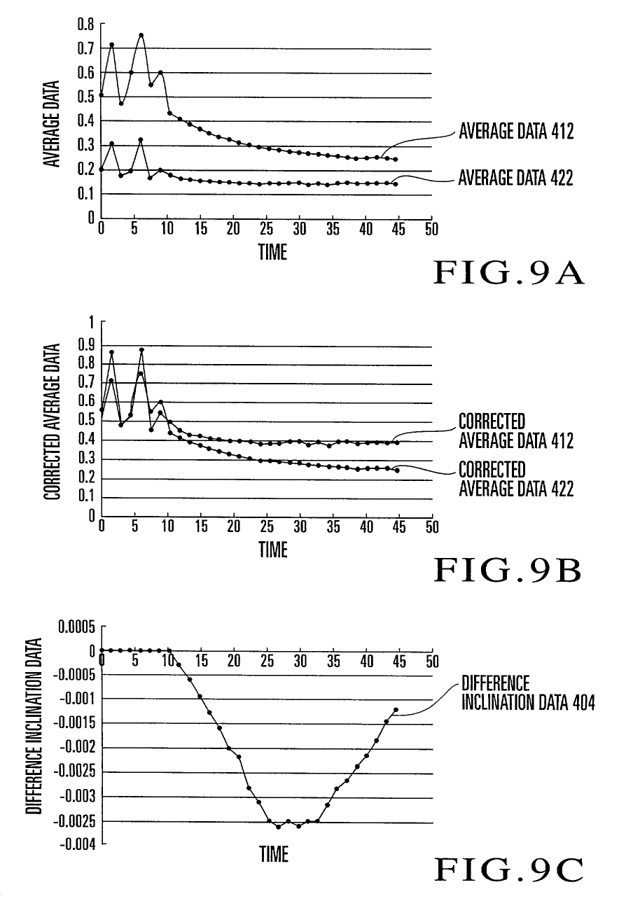

Three graphs shown in FIGS. 9A to 9C are representative graphs in the second embodiment, and show polishing progress after removal of the metal film, i.e., temporal changes in reflected light quantity signal. FIG. 9A shows temporal changes in the average data 412 and 422 during polishing. FIG. 9B shows temporal changes in the corrected average data 412 and 422 after the average data 412 and 422 during polishing of the metal film 201 are corrected to coincide with each other. FIG. 9C shows temporal changes in difference inclination data based on the corrected average data 412 and 422 during polishing.

Similar to the first embodiment, the average calculation unit 411 averages reflected light quantities obtained during one rotation of the wafer 1 and stores the average as average data 412, in order to cause the arithmetic units 416 and 426 to execute algorithms prepared for the first and second measurement systems. Also in the second measurement system, the average calculation unit 421 calculates and records the average data 422.

To remove the noise component of the average data, similar to the first embodiment, the inclination calculation unit 413 in the first measurement system receives the average data 412, calculates the average inclination, and outputs it as the inclination data 414. Also in the second measurement system, the inclination calculation unit 423 receives the average data 422 and outputs the inclination data 424.

If the arithmetic units 416 and 426 execute the algorithm A for the obtained inclination data 414 and 424, the end point of polishing cannot be detected because no average data increases.

The graphs of FIGS. 9A and 9B exhibit the following characteristic changes (1) to (3) along with polishing progress.

(1) A relatively large change appears at the beginning of polishing.

(2) The reflected light quantity decreases. At this time, the change rates of the average data 412 and 422 are different during polishing, and their difference becomes larger.

(3) After polishing, the light quantity change rate of the average data 412 in the first measurement system and that of the average data 422 in the second measurement system become almost equal, and the difference become constant.

In (1), the relatively large change appears at the beginning of polishing until the wafer 1 and a polisher 2 adapt to each other, and is a change irrespective of polishing progress in the initial unstable region. In (2), the decrease in reflected light quantity is a change as the barrier film 202 becomes thinner along with polishing progress. This change occurs because the barrier film 202 becomes thinner on the wafer surface along with polishing progress and the underlying layer of the barrier film 202 is exposed to decrease the occupation ratio of the barrier film 202.

In FIG. 9B, the two corrected average data of different wavelengths exhibit different change rates, and their difference becomes larger. This occurs because the reflectance of the barrier film including a underlying structure and interference changes depending on the wavelength. Since correction is done using the reflectance of the metal film 201 as a reference, the occupation ratio of the barrier film 202 decreases along with polishing progress, and the reflectance changes for a different wavelength in the underlying structure after the barrier film 202 is removed. The change rates are also different, so that the difference becomes larger.

In (3), the reflectance at each wavelength depends on the underlying structure at a low occupation ratio of the barrier film 202. Thus, the change rate of each reflected light quantity stabilizes, and the two corrected average data stabilize with a difference.

After the metal film 201 is removed, the average data 412 is smaller in reflected light quantity than the average data 422, as shown in FIG. 9B. This is because the decrease ratio of the reflected light quantity is determined by the difference in reflectance between the wavelengths on the barrier film 202. After this time point, i.e., after the start of inspection, the barrier film 202 becomes thinner and starts transmitting light, which increases the influence of the underlying layer. The difference between the first average data 412 and the second average data 422 increases, maximizes at the end point of polishing, and then keeps constant.

This means the end point of polishing. The reflected light quantity stabilizes at the reflectance of the underlying structure after removal of the barrier film, as described in the first embodiment. The reflected light quantities, i.e., average data of the respective wavelengths stabilize. At this time, the difference between the average data of the first and second measurement systems becomes constant. Hence, the end point of polishing can be detected by detecting a time point when the difference in decrease ratio between the first average data 412 and the second average data 422 becomes constant at the end point of polishing after the difference increases toward the end point of polishing.

The end point detection device 152 shown in FIG. 8 will be described.

The average calculation units 411 and 421 calculate the average data 412 of the first measurement system and the average data 422 of the second measurement system, respectively. The difference calculation unit 401 multiplies the average data 412 obtained from the first measurement system by the correction magnification of the first measurement system prepared by reference light quantity correction, thus calculating the corrected first average data. Similarly, the corrected second average data is calculated. The difference calculation unit 401 calculates the difference between the first and second average data, and outputs the difference data 402.

Since the difference data 402 contains a noise component due to nonuniformity in removal of the metal film, nonuniformity of polishing progress, measurement precision nonuniformity, or mixture of noise, the noise component of the difference data 402 must be sufficiently smoothed. For this purpose, the difference inclination calculation unit 403 calculates the average inclination of a plurality of data preceding by a predetermined number of data containing the current value among the difference data 402, and outputs the difference inclination data 404. The obtained difference inclination data 404 changes over time with the waveform shown in FIG. 9C.

The arithmetic unit 406 detects as the end point of polishing a time point when the difference data becomes constant after an increase. Since the end point of polishing is detected when the difference data becomes constant, a time point when the difference inclination data comes close to 0 is detected. A value for determining whether the difference inclination data comes close to 0 is defined as an end point determination threshold. If the absolute value of the difference inclination data 404 falls within the end point determination threshold successively a predetermined number of times or more, the arithmetic unit 406 determines the end point of polishing. Alternatively, the arithmetic unit 406 determines the end point of polishing when the absolute value of the difference inclination data falls within the end point determination threshold a predetermined number of times or more after it reaches the predetermined value or more, or when the difference inclination data 404 falls within the end point determination threshold at a predetermined ratio or more.

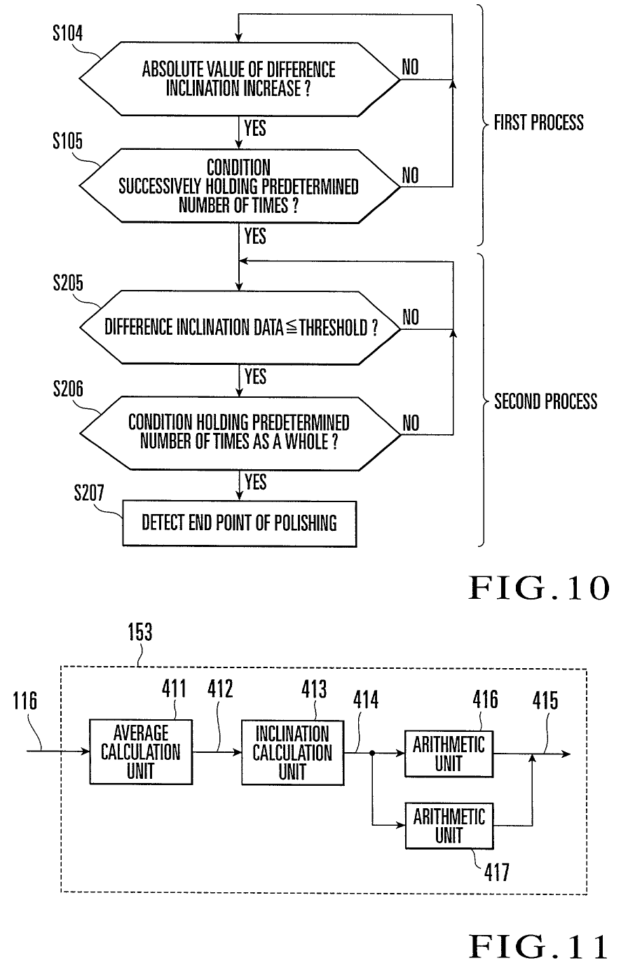

Execution of an algorithm by the arithmetic unit 406 will be described with reference to FIG. 10 by exemplifying a case wherein the end point of polishing is determined when the difference inclination data 404 falls within the end point determination threshold at a predetermined ratio or more.

In the first process of executing the algorithm B, the arithmetic unit 406 checks whether the absolute value of the difference inclination increases, in order to detect that the absolute value of the difference inclination becomes large once (step S104). If Yes in step S104, the arithmetic unit 406 checks whether the condition that the absolute value of the difference inclination increases succeeds a predetermined number of times, in order to prevent erroneous determination caused by abrupt noise or the like (step S105).

The arithmetic unit 406 shifts to the second process. The arithmetic unit 406 determines whether the difference inclination data reaches a predetermined threshold or less, in order to detect a time point when the difference becomes almost constant upon increasing once (step S206). That is, the arithmetic unit 406 determines whether the difference inclination data 404 reaches the end point determination threshold around 0. Also in this case, the arithmetic unit 406 checks whether the condition has been satisfied a predetermined number of times as a whole, in order to prevent erroneous determination caused by abrupt noise or the like (step S206). If Yes in step S206, the arithmetic unit 406 detects the end point of polishing (step S207).

To absorb variations in the light quantity of the light source or the like and keep the determination reference constant, the end point determination threshold is calculated by multiplying the first reference reflected light quantity by a predetermined value.

(Third Embodiment)

The third embodiment is the same as the first embodiment except that an algorithm C different from the algorithm A in the first embodiment is executed parallel. A description up to calculation of inclination data 414 is omitted, and end point detection operation will be described with reference to the block diagram of FIG. 11 showing the internal arrangement of an end point detection device 153.

The inclination data 414 is input parallel to an arithmetic unit 416 for executing the algorithm A and an arithmetic unit 417 for executing the algorithm C. The arithmetic unit 417 detects that the reflected light quantity does not change, i.e., the inclination data 414 comes close to 0, and outputs an end point detection signal 415. The arithmetic unit 416 for executing the algorithm A and the arithmetic unit 417 for executing the algorithm C can operate parallel to each other. Either of parallel operation and the operation of only one arithmetic unit can be arbitrarily selected. Note that the end point of polishing can be detected on different types of wafers by parallel-operating a plurality of algorithms.

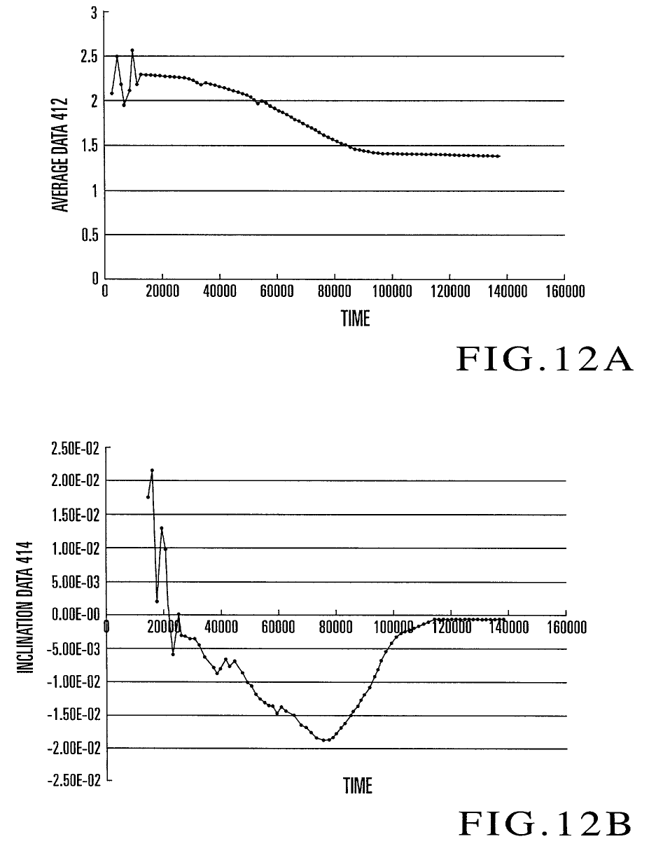

FIG. 12A shows temporal changes in average data 412 during polishing, and FIG. 12B shows temporal changes in the inclination data 414 during polishing. This exemplifies a case wherein the end point of polishing cannot be detected even by the algorithm A of the first embodiment or the algorithm B of the second embodiment. For example, changes in the reflectance of a metal film at a selected wavelength, changes in the reflectance of a barrier film 202 including the influence of the underlying layer, and changes in the reflectance of the underlying layer are similar between respective wavelengths depending on the barrier film thickness and underlying structure.

In FIGS. 12A and 12B, the average data exhibits the following characteristic changes (1) to (4) along with polishing progress.

(1) A relatively large signal change appears at the beginning of polishing.

(2) The reflected light quantity decreases. At this time, the change rate relatively greatly changes.

(3) The change rate gradually decreases without increasing the reflected light quantity.

(4) The reflected light quantity stabilizes.

In (1), the relatively large change appears at the beginning of polishing until the wafer 1 and polisher 2 adapt to each other, and is a change irrespective of polishing progress in the initial unstable region. In (2), the decrease in reflected light quantity is a change as the barrier film becomes thinner along with polishing progress. This occurs because the reflectance of the film below the barrier film 202 and that of the barrier film 202 including the interference effect are lower than the reflectance of a metal film 201 and the occupation ratio of the barrier film on the wafer surface decreases along with polishing progress. The change rate increases because the reflectance of the metal film 201 is much higher than that of the underlying structure and that of the metal film 201 including the interference effect.

In (3), the change rate of the reflected light quantity decreases because the barrier film 202 is substantially polished on the polished wafer surface, the occupation ratio of an underlying insulating film 203 increases, and the influence of the barrier film 202 is reduced. In (4), the reflected light quantity stabilizes because the barrier film 202 is removed from the polished wafer surface and the reflected light quantity stabilizes at the reflectance of the underlying layer.

Polishing ends when the change rate increases once and then comes close to 0. This time point is detected.

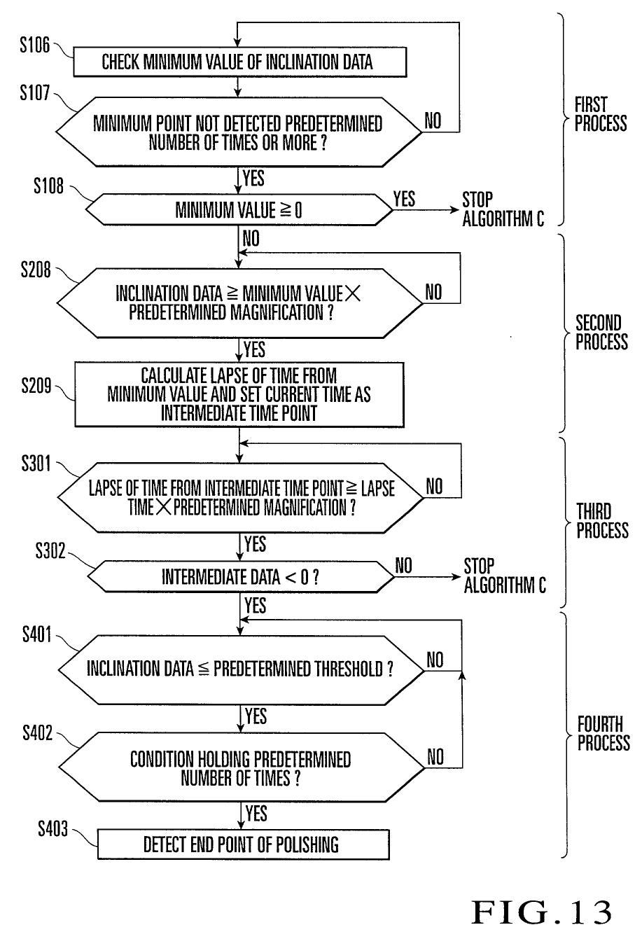

The operation of the algorithm C executed by the arithmetic unit 417 will be explained with reference to FIG. 13.

In the first process of executing the algorithm C, the arithmetic unit 417 detects the minimum point of inclination data, and holds the time taken from the start of polishing to detection of the minimum point. The arithmetic unit 417 checks the minimum value of the inclination data (step S106), and if the value is minimum, holds this value and the time taken from the start of polishing. The arithmetic unit 417 detects whether the minimum point has been detected a predetermined number of times or more (step S107). If Yes in step S107, the arithmetic unit 417 checks whether the minimum value is 0 (step S108). If Yes in step S108, the arithmetic unit 417 stops detection by the algorithm C; if the minimum value is negative, advances to the second process.

The minimum value is checked to detect that the reflected light quantity decreases along with polishing progress but gradually changes as the barrier film 202 becomes thinner. More specifically, the arithmetic unit 417 holds the minimum value of the inclination data and the time taken from the start of polishing (when the reflected light quantity most greatly changes). To prevent erroneous determination under the influence of abrupt noise or the like, the arithmetic unit 417 detects that the inclination data is coming close from a large negative value to 0 when the minimum value is not detected successively a plurality of number of times. The minimum value of 0 or more means an increase in reflective light quantity. In this case, the algorithm C may start midway along the pattern where the reflected light quantity increases, as described in the first embodiment. Thus, the algorithm C itself stops not to erroneously detect the end point of polishing by the algorithm C.

The arithmetic unit 417 shifts to the second process and determines “inclination data≧minimum value×predetermined magnification” (step S208). At this time, the arithmetic unit 417 waits until the inclination data increases from the minimum value by a predetermined magnification. Note that the minimum value is multiplied by the predetermined magnification in order to obtain an intermediate time point inevitable to predict the time until the inclination data comes close to 0. When the line which connects the minimum value to a value around 0 is regarded as a straight line, and the minimum value is multiplied by, e.g., ½ the minimum value as a predetermined magnification, the inclination data can be predicted to be 0 after the lapse of a time twice the time until the inclination data reaches the predetermined magnification from the minimum value.

The arithmetic unit 417 calculates the lapse of time from the minimum value, and holds the current time as an intermediate time point (step S209). Further, the arithmetic unit 417 holds as the lapse of time from the minimum value a time required from detection of the minimum value to the intermediate time point.

In the third process, ½ the time taken from the minimum value to 0 has elapsed upon the lapse of time of the inclination data from the minimum value at a predetermined magnification of, e.g., ½ in the determination of step S208. Thus, the inclination data can be predicted to reach 0 when the same time as the lapse of time from the intermediate time point, i.e., the time at a predetermined magnification of 1 has elapsed. However, an error occurs in the time when the inclination data is predicted to reach 0 by linear approximation because of slow changes around the minimum value. With the function of checking whether the waveform of the first embodiment is erroneously recognized, the predetermined magnification in step S301 is, e.g., 0.9 smaller than 1 for a predetermined magnification of ½ in step S208.

The arithmetic unit 417 checks whether the inclination data is 0 or more (step S302), and checks whether the waveform to be detected by the algorithm described in the first embodiment is erroneously recognized. If the inclination data is 0 or more, the arithmetic unit 417 stops execution of the algorithm C; if No in step S302, the arithmetic unit 417 shifts to the fourth process.

The third process is done to confirm that the reflected light quantity described in the first embodiment does not increase. If the reflected light quantity increases at a time point when the inclination data is predicted to come close to 0, the change rate of the inclination data does not decrease, and the inclination data linearly changes to a positive value. Thus, an increase in reflected light quantity can be determined under the condition of step S302. The inclination data gradually changes from the minimum value till the lapse of a short time, and then linearly changes. The inclination of the straight line is calculated from the minimum value, so that the inclination is more moderate than that of the actual linear change. For this reason, the lapse of time is multiplied by a predetermined magnification to shift the predicted time in step S301, instead of multiplying the inclination by the magnification. The predetermined magnification is set to 0.9 or the like.

If the inclination data value is positive at the time point when the resultant inclination data is predicted to be 0, the inclination data draws the graph of FIG. 5B, and the arithmetic unit 417 stops execution of the algorithm C. If the inclination data value is negative, the arithmetic unit 417 advances to the fourth process.

In the fourth process, the end point of polishing is determined if the condition that the inclination data is smaller than a predetermined threshold around 0 is satisfied by a predetermined number of times as a whole. More specifically, the arithmetic unit 417 checks whether the inclination data is a predetermined threshold or less (step S401), detects that the reflected light quantity stabilizes because the inclination data becomes smaller than the predetermined threshold around 0, and determines the end point of polishing. At this time, the arithmetic unit 417 checks whether the determination condition of step S401 is satisfied a predetermined number of times, in order to prevent erroneous detection caused by abrupt noise or the like (step S402). The predetermined threshold is set in advance by multiplying the first reference reflected light quantity by a predetermined value.

On the temporal change graph of the reflected light quantity, the reflected light quantity gradually decreases for a large reference reflected light quantity, but changes as if it does not keep decreasing for a small reflected light quantity. From this, the end point of polishing is detected by a relative threshold with respect to the change amount from the reference reflected light quantity.

(Fourth Embodiment)

The first to third embodiments are based on the condition that swings of the polisher 2 do not obstruct the measurement system. However, in a semiconductor wafer polishing apparatus such as a CMP apparatus, the polisher 2 may shield the optical path of inspection light or reflected light, and the swing range of the polisher 2 may overlap an irradiation position. The fourth embodiment concerns a polishing end point detection method when the polisher 2 influences the measurement system.

As one method of detecting that swings of the polisher 2 influence the measurement system, a sensor is attached to the swing shaft of the polisher 2 to detect the range where the measurement system is influenced. As another method, whether the measurement system is influenced is detected from data, i.e., by detecting that a reflected light quantity signal becomes smaller than 0 or a predetermined value around 0.

In the latter case, the wavelength of inspection light must be carefully selected not to reduce spectral reflection to 0 or an extremely small value owing to the composition of the layer structure of a semiconductor wafer. In either case, whether the measurement system is obstructed is determined by using the sensor or from a data value. An example using the sensor will be described below.

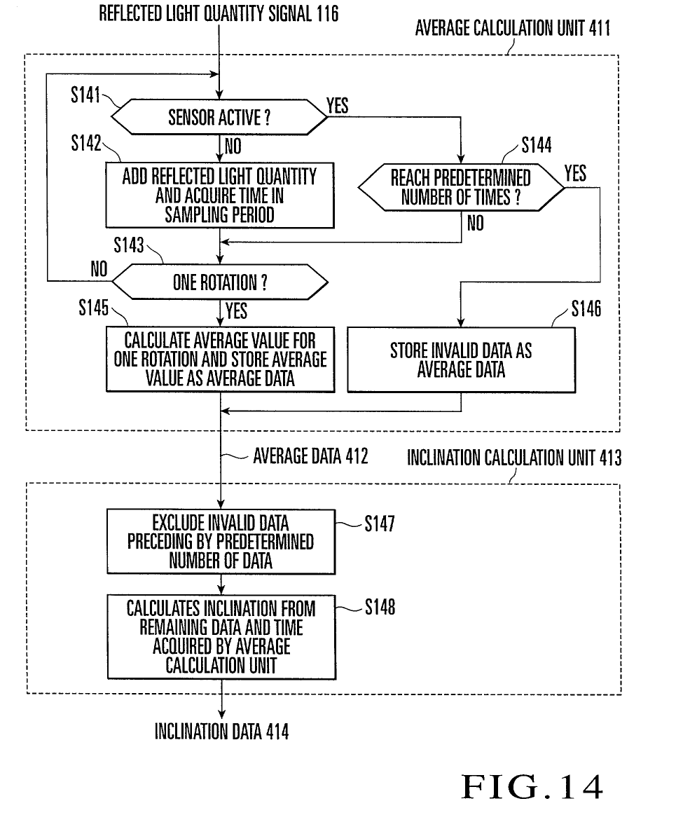

In the fourth embodiment, only the average calculation unit, inclination calculation unit, and difference inclination calculation unit in each of the first to third embodiments are changed. The arrangement and the like are the same as those in each embodiment. The fourth embodiment will exemplify the average calculation unit 411 and inclination calculation unit 413 in the first embodiment. FIG. 14 shows the detailed flow of the average calculation unit 411 and inclination calculation unit 413. Assume that the polisher 2 influences the measurement system when the sensor is active.

The average calculation unit 411 checks whether the sensor is active (step S141). If Yes in step S411, the average calculation unit 411 determines whether the sensor becomes active during one rotation a predetermined number of times (step S144). If Yes in step S144, a value impossible to be average data is stored as invalid data (step S146). For example, a negative value is stored when average data does not take any negative value, or an extremely large value is stored, thus distinguishing the invalid data from normal average data.

If No in step S141, the average calculation unit 411 adds reflected light quantity signals for one rotation in the sampling period. The average calculation unit 411 acquires time every sampling (step S142). The sampling period during one wafer rotation must be a small value which prevents the reflected light quantity from being influenced by the density of an interconnection pattern on the wafer surface and enables satisfactorily recognizing a wafer polishing state.

For example, the sampling period is calculated from the diameter and path length of inspection light and the time of one rotation (rotational period). If the sampling period is small enough to draw a continuous locus, the reflected light quantity can be uniformly measured on the circumference irradiated with the inspection light. However, the sampling period may be longer as far as the wafer polishing state is satisfactorily recognized by the average of one rotation because, e.g., patterns are less rough and fine.

After one rotation (step S143), the average calculation unit 411 calculates the average of the added reflected light quantity for one rotation and the acquisition time (step S145). The average of the reflected light quantity can be obtained by dividing the added reflected light quantity by the number of sampling operations, and is stored as average data 412. As for time acquisition, any one of the first sampling time, last sampling time, and average sampling time is set as the acquisition time of average data. The average data 412 containing the acquisition time is output to the inclination calculation unit 413.

High-precision measurement cannot be achieved unless the predetermined number of times in step S144 must be set to a value which sufficiently decreases the ratio of the number of data which become invalid when the sensor is active, to the number of data obtained by sampling of one rotation in consideration of changes in reflected light quantity. From this, the predetermined number of times in step S144 is set smaller than the number of times the determination precision does not decrease. This is because sparse and dense patterns are aligned on a wafer, a reflected light quantity signal 116 changes mainly depending on the density of interconnection portions 204, and the reflected light quantity signal 116 periodically changes, as described in the first embodiment.

The inclination calculation unit 413 excludes invalid data preceding by a predetermined number of data (step S147), calculates an inclination from the remaining data and the time acquired by the average calculation unit 411, and calculates the average of the inclination (step S148). In step S147, invalid data preceding by a predetermined number of data are excluded because the average data 412 contains a noise component owing to nonuniformity of polishing progress, measurement precision nonuniformity, or mixture of noise, as described in the first embodiment. To calculate the average of the inclination from the average data from which the invalid data are excluded, the inclination is calculated from the sum of two average data preceding by a predetermined number of data among average data and the time difference obtained by the average calculation unit 411.

The method described in the fourth embodiment can detect the end point of polishing by using valid average data as a reflected light quantity when swings of the polisher 2 influence the measurement system for only the initial or last short time of one rotation, or when the swing speed of the polisher 2 is very high in comparison with the time taken for a wafer 1 to rotate once and the polisher 2 influences the measurement system for only a short time. If the time when the polisher 2 influences the measurement system is much longer than the time taken for one rotation, the sensor is checked only immediately before and after the start of data acquisition during one rotation of the wafer 1 without checking the sensor every sampling. The end point of polishing can be detected by excluding data as invalid average data when the sensor is active immediately before and/or after the start of data acquisition, and using the remaining valid average data as a reflected light quantity.

The end point of polishing may be detected with a delay if the ratio of average data under the influence of swings of the polisher 2 on the measurement system is high in the method described in the fourth embodiment. If the measurement system is almost always influenced during polishing, the end point of polishing cannot be detected. From this, about ⅓ or more of all average data are desirably valid.

The first to fourth embodiments have exemplified one irradiation position A. The fifth embodiment will describe a polishing end point detection method in which a plurality of irradiation positions are prepared radially along a wafer, measurement systems according to the first, second, and third embodiments are arranged at the respective irradiation positions, and the fourth embodiment is applied to an irradiation position where swings of the polisher 2 influence the measurement system.

To detect the end point of polishing at a plurality of irradiation positions, end point detection changes for each irradiation position owing to polishing nonuniformity, and delays at an irradiation position where polishing slowly progresses. If swings of the polisher 2 influence the measurement system, as described in the fourth embodiment, invalid data under the influence of swings is merely estimated by linear interpolation of preceding and succeeding valid average data, and a delay occurs in detecting that average data is asymptotic to a certain value.

The fifth embodiment provides a polishing end point detection method which guarantees an end point detection delay. Sparse and dense patterns are aligned on a wafer, and a reflected light quantity signal changes mainly depending on the density of interconnection portions. Since the wafer rotates, the average of the reflected light quantity, i.e., average data upon one rotation is almost the same between respective irradiation positions so long as the polishing state is the same. The end point of polishing is detected by an algorithm D of determining the end point of polishing when average data at an irradiation position where detection of the end point delays becomes almost the same as average data at an irradiation position where the end point has first been detected. This can prevent excessive polishing caused by a detection delay of the end point of polishing.

(Fifth Embodiment)

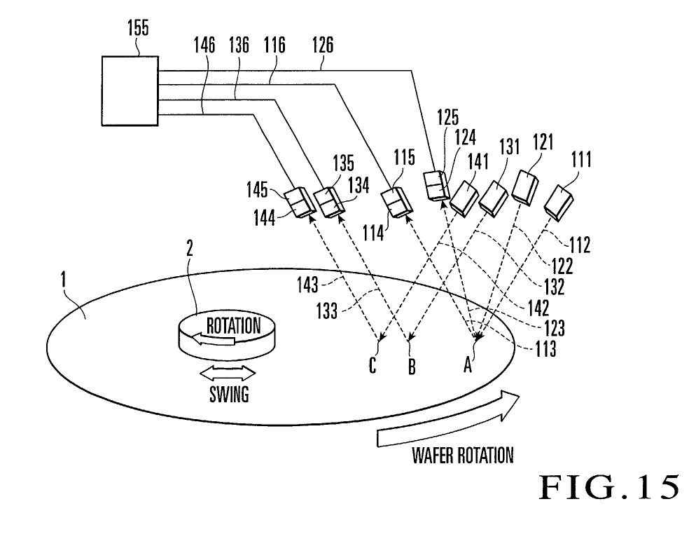

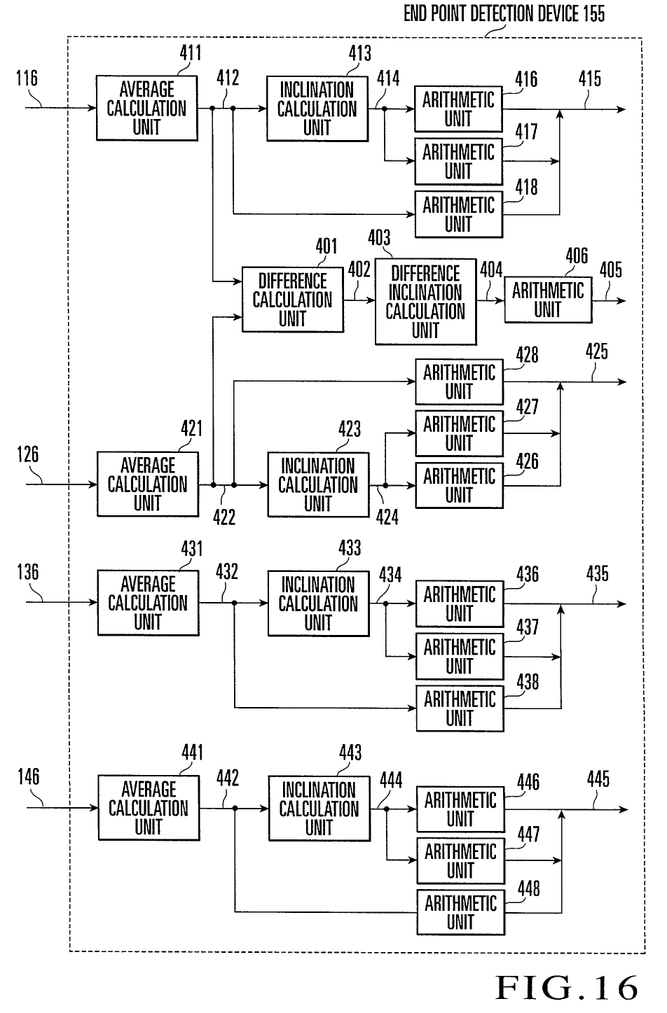

FIG. 15 shows the schematic arrangement of a semiconductor wafer polishing end point detection apparatus according to the fifth embodiment of the present invention.

In FIG. 15, first and second measurement systems as described in the second embodiment are arranged at an outermost irradiation position A of a wafer 1, and independently detect the end point of polishing by parallel operation of the algorithms A and C. The first and second measurement systems parallel-detect the end point of polishing by the algorithm B described in the second embodiment. A fourth measurement system for detecting the end point of polishing by parallel operation of the algorithms A and C is arranged in correspondence with a centermost irradiation position C. A third measurement system for detecting the end point of polishing by parallel operation of the algorithms A and C is arranged in correspondence with an irradiation position B between the irradiation positions A and C.

As for the wavelengths of the respective measurement systems, their reflected light quantities cannot be compared at different spectral reflectances. For this reason, the first and second measurement systems have a wavelength which increases the reflectance of a metal film 201, as described in the second embodiment. The third and fourth measurement systems have the same wavelength as that of the first and second measurement systems. As for the irradiation diameter, the same diameter facilitates comparison because comparison is simple under the same conditions. Different irradiation diameters cause a time shift under the influence of surroundings. The fourth embodiment is applied to the irradiation positions A and B where swings of a polisher 2 are assumed not to influence the measurement systems, and to the irradiation position C where swings of the polisher 2 are assumed not to influence the measurement system.

The arrangement of each measurement system has already been described in each embodiment, and a description thereof will be omitted. A single or many repetitive combinations can be applied to the layout and embodiment of the measurement systems.

FIG. 16 shows the arrangement of an end point detection device 155 according to the fifth embodiment. The arrangement (arithmetic unit, average calculation unit, and inclination calculation unit) except for an arithmetic unit for executing the algorithm D has already described in the first to fourth embodiments, and only the unit concerning the algorithm D will be explained.

To detect the end point of polishing at the irradiation position A, average data 412 in the first measurement system is parallel-input to an inclination calculation unit 413 and an arithmetic unit 418 for executing the algorithm D. Average data 422 in the second measurement system is parallel-input to an inclination calculation unit 423 and an arithmetic unit 428 for executing the algorithm D. To detect the end point of polishing at the irradiation position B, average data 432 in the third measurement system is parallel-input to an inclination calculation unit 433 and an arithmetic unit 438 for executing the algorithm D. To detect the end point of polishing at the irradiation position C, average data 442 in the fourth measurement system is parallel-input to an inclination calculation unit 443 and an arithmetic unit 448 for executing the algorithm D. The arithmetic units 418, 428, 438, and 448 parallel-process the algorithm D.

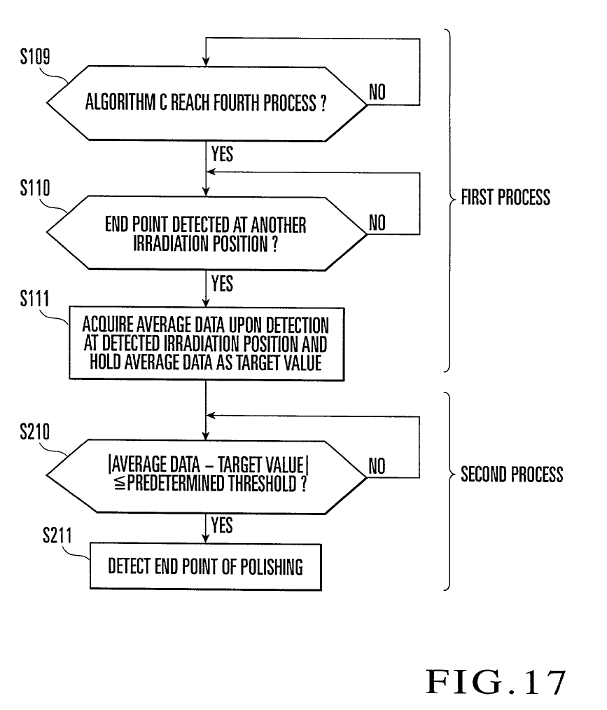

The operation of the algorithm D will be described with reference to FIG. 17 by exemplifying a case wherein the end point of polishing is first detected at the irradiation position A and at this time, polishing progress delays at the irradiation position C.

The fourth measurement system corresponding to the irradiation position C incorporates an optical system having the same wavelength, same diameter, and same irradiation angle as those of the first and third measurement systems. In the first process of executing the algorithm D, whether the algorithm C has reached the fourth process is checked (step S109). The fourth measurement system waits until the algorithm C described in the third embodiment reaches the fourth process because of the following reason. If the end point of polishing is detected at the irradiation position A, the average data 412 in the first measurement system is compared to the average data 442 in the fourth measurement system. At this time, the value of the average data 412 at the end point of polishing with an increase in reflected light quantity described in the first embodiment exists even before the end point of polishing. The average data 442 in the fourth measurement system must be prevented from being erroneously detected with the same value before the end point of polishing, and one of conditions for reaching the fourth process of the algorithm C is that the average data does not increase.

The algorithm D waits until the end point of polishing is detected at another irradiation position (step S110), in order to allow the algorithm D to exploit the average data 412 at the polishing end point at the irradiation position A. If the end point of polishing is detected at another irradiation position, the average data upon detection is held as a target value (step S111). However, the second measurement system uses a different spectral reflectance due to a different wavelength, so average data in the second measurement system cannot be used as a target value. The same effects can also be obtained in order of step S110→step S111→step S109, and thus the order of the first process may be changed.

The algorithm D advances to the second process to determine|average data−target value|≦ predetermined threshold (step S210). The average data 412 at the end point of polishing detected at the irradiation position A is compared with the average data 442 at the irradiation position C, but they may not exhibit the same value depending on the measurement precision. For this reason, when the absolute value of the difference between the average data 442 and the target value is equal to or smaller than a predetermined threshold, the end point of polishing is determined. The predetermined threshold is set to a value around 0 in consideration of a measurement error.

According to the fifth embodiment, the end point of polishing can be detected even when the end point of polishing can be detected by only the algorithm B of the first and second measurement systems at the irradiation position A, when the end point of polishing can be detected by only the algorithm A of a measurement system (e.g., second measurement system) having a wavelength different from that of the fourth measurement system, or when only one measurement system is arranged, like the irradiation positions B and C. As a result, the end point of polishing can be detected at respective points on the wafer surface without leaving any unpolished portion.

The sixth embodiment enables displaying polishing nonuniformity even during polishing when the end point of polishing is detected at a plurality of irradiation positions. This embodiment utilizes the fact that average data at the end point of polishing is the same on wafers of the same type or wafers having similar pattern densities.

Assuming that a metal film is exposed at the start of wafer polishing and an insulating film after removal of a barrier film is exposed at the end point of polishing, average data draws a falling curve as a whole from the start of polishing toward the end point of polishing. The current polishing progress degree can be attained from average data at the end point of polishing on a wafer of the same type or a wafer having a similar pattern density. The polishing progress degree is displayed for each irradiation position, thereby confirming polishing nonuniformity from the difference in the polishing progress degree.

As a polishing progress degree calculation equation, letting AVs be average data on a metal film, AVe be average data at the end point of polishing on a previously polished wafer of the same type or a wafer having a similar pattern density, and AVn be average data during polishing, a polishing progress degree AVr is given by

AVr=(AVn−AVe)/(AVs−AVe) (3)

The value calculated by equation (3) is multiplied by 100 and expressed as a percentage, which enables sensitively estimating the remaining polishing amount. Note that when the barrier film 202 becomes thin and the underlying structure raises average data, like the first embodiment, a negative value is displayed once, and the average data is used as a yardstick.

Even in this case, however, the progress degrees of all algorithms can be displayed to accurately estimate the remaining polishing amount from the polishing progress degree and the progress degrees of the algorithms. In some cases, small changes are difficult to recognize even if changes in average data as a function of the time are actually displayed on a graph in real time. According to the sixth embodiment, the progress of each algorithm is displayed to display a process executed in the algorithm and the progress of counting in the loop of the process. Thus, the time when the algorithm or process ends can be easily estimated.

As a display example in the algorithm D, “ALG4:ALG_C wait for the fourth process” is displayed during step S109 “whether algorithm C reaches fourth process?” in the first process of the algorithm D. “ALG4: wait for detection at another point” is displayed during step S110 “end point detected at another irradiation position?”. “ALG4:aaaa≦bbbb wait” is displayed during step S210 “average data—target value ≦predetermined threshold?” in the second process. At this time, the progress degree of the algorithm D can be recognized by displaying the difference of “average data —target value” at aaaa and “predetermined threshold” at bbbb.

This processing is performed for all measurement systems and algorithms, and the polishing progress degree is obtained for each irradiation position from the polishing progress degree and the progress degrees of the algorithms, thereby attaining the degree of polishing nonuniformity.

(Seventh Embodiment)

In the fourth embodiment, a data portion lost by invalid data generated by swings of the polisher 2 is interpolated as a straight line by preceding and succeeding valid data, and then saved. However, this inevitably decreases the detection precision because changes in reflected light quantity along with polishing progress draw a curve. The seventh embodiment checks the polishing progress degree described in the sixth embodiment at an irradiation position where the measurement system is obstructed by swings of a polisher 2. Lost data is interpolated at an irradiation position or by a measurement system exhibiting the most similar progress degree, thus increasing the polishing end point detection precision.

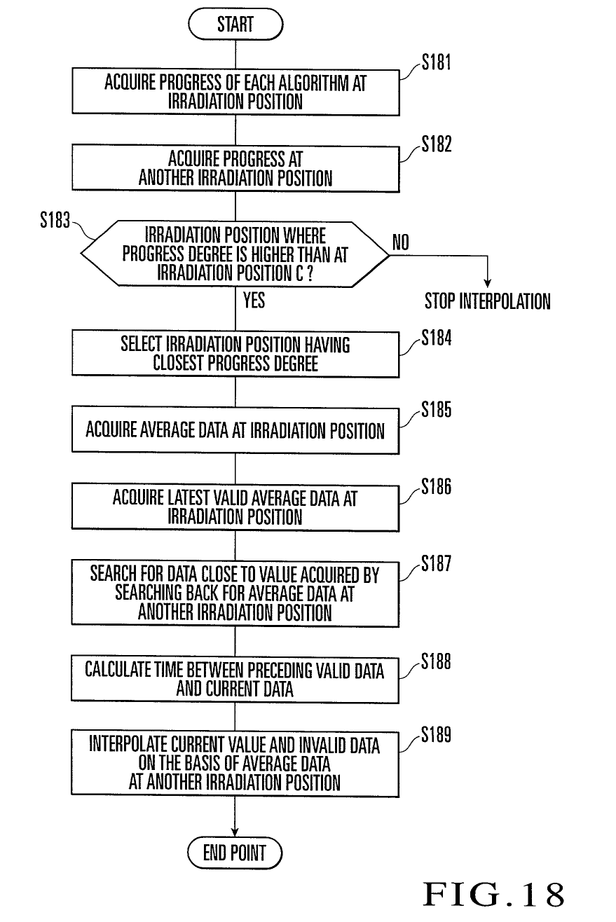

FIG. 18 shows the operation flow of the seventh embodiment. In FIG. 18, assume that the polishing progress degree is almost the same between the irradiation positions A and C (or polishing slightly progresses at the irradiation position A), and polishing progresses more at the irradiation position B than the irradiation position A in the arrangement described in the fifth embodiment.

The progress of each algorithm at the irradiation position C is acquired (step S181), and weighting is done to set the detection time point as 100 in all the algorithms. In this case, the progress degree is expressed by displaying the achievement by %, or by quantitatively displaying a predetermined numbered loop or “maximum value×predetermined magnification or less” loops for each step because the number of steps or loops is different between algorithms. For example, as shown in matrixed Table 1, “current process number/total number of processes” is stored as process information for each algorithm of a measurement system. “Current number of times/predetermined number of times” representing a predetermined numbered loop in a process, or “current value/(maximum value×predetermined magnification)” representing “maximum value×predetermined magnification or less?” wait loops is stored as progress information for each algorithm of a measurement system. In Table 1, progress information “1” represents an achievement of 100%.

TABLE 1

| | | | |
|---|---|---|---|
| Algorithm A | Algorithm B | Algorithm C | Algorithm D |

| | Process | Progress | Process | Progress | Process | Progress | Process | Progress |
|---|---|---|---|---|---|---|---|---|
| First | 1/2 | 1/3 | 1/2 | 0/3 | 3/14 | 6/15 | 1/2 | 0 |
| Measurement | | | | | | | | |
| System | | | | | | | | |
| Second | 1/2 | 0/3 | 1/2 | 0/3 | 3/4 | 1/18 | 1/2 | 0 |
| Measurement | | | | | | | | |
| System | | | | | | | | |
| Third | 1/2 | 2/3 | 0 | 0 | 2/4 | 3/15 | 1/2 | 0 |
| Measurement | | | | | | | | |
| System | | | | | | | | |
| Fourth | 1/2 | 1/3 | 0 | 0 | 3/4 | 5/15 | 1/2 | 0 |
| Measurement | | | | | | | | |
| System | | | | | | | | |

In Table 1, one measurement system corresponds to each of the irradiation position B concerning the third measurement system and the irradiation position C concerning the fourth measurement system, cannot execute the algorithm B, and thus stores “0” which means no progress. The first and second measurement systems correspond to the irradiation position A, and store the same value as process information. In the fourth measurement system, the algorithm C most progresses, and process information “3/4” and progress information “5/15” mean completion of about ⅓ the third process. This will be described in detail below. In this manner, the values of processes are compared for each measurement system, and a value closest to 1 or the largest value is extracted.

The flow chart shown in FIG. 18 will be explained from the beginning with reference to Table 1.

The fourth measurement system corresponding to the irradiation position C is determined to be influenced, and the progress degrees of respective algorithms in the fourth measurement system are acquired (step S181). Then, the progress degrees of algorithms in the first to third measurement systems are acquired (step S182). Whether an irradiation position where the progress degree is higher than that at the irradiation position C is checked (step S183) to find that the third measurement system at the irradiation position B and the first measurement system the irradiation position A have higher progress degrees than that at the irradiation position C.

The difference in progress between the fourth measurement system at the irradiation position C to be compared and another measurement system at another irradiation position can be determined simply from process information and progress information for the same algorithm. If algorithms are different, a determination error may occur due to an increase in average data as described in the first embodiment, and a measurement system using a different algorithm may be excluded. For the same algorithm, a progress degree is compared with that of the fourth measurement system to search for a measurement system which progresses more than the fourth measurement system. If the progress degree is highest at the irradiation position C, interpolation stops, and data is recorded as invalid data on average data.

An irradiation position having the most similar progress degree is selected from irradiation positions which satisfy the condition of step S183 (step S184). That is, the progress degrees of algorithms at the irradiation position C and another irradiation position are compared to search for an irradiation position having the same or slightly higher progress degree. In this case, the first measurement system at the irradiation position A that completes about “6/15” the third process of the algorithm C slightly progresses with the same progress degree as that of the irradiation position C, and the difference is only 1/15. As a search method, a progress degree is compared with that of the fourth measurement system, and a measurement system having a higher progress degree as that of the fourth measurement system is searched.

Average data in the measurement system which has been searched by step S184 and has a higher and most similar progress degree as that of the irradiation position C (fourth measurement system) is acquired (step S185). In this case, average data are current average data in the first measurement system at the irradiation position A, and are assumed to be 4.4, 4.6, 4.7, 4.9, 5, . . . in reverse chronological order.

Then, the latest valid average data at the irradiation position is acquired (step S186). In this case, valid data which is first found by searching back for data at the irradiation position C (fourth measurement system) from the present to the past is extracted as preceding average data as far as the value has always been interpolated. If, however, preceding data is invalid in step S183, data preceding by another rotation are searched until valid data is found. If no valid data is found, the flow ends. Assume that preceding average data in the fourth measurement system is invalid, and data preceding by one rotation is “4.8”.

Data close to a value acquired by searching back for average data at another irradiation position is searched (step S187). As described in step S185, values close to the data “4.8” preceding by two rotations as valid data at the irradiation position C (fourth measurement system) are the values of data preceding by three rotations and four rotations at the irradiation position A (first measurement system). In this case, data “4.7” preceding by three rotations is found by sequentially searching back for data from the present to the past. In search, an allowable ratio is set in advance. Data first found within this ratio may be used, or search may start from data which exceeds the ratio.

The time from the preceding valid data to the current data is calculated (step S188). This time represents the lapse of time from detection of “4.8” at the irradiation position C to the present. This lapse of time means a time of two rotations because invalid data of one rotation exists.

The current value and invalid data are interpolated based on the average data at the other irradiation position (step S189). The current value and invalid data “4.8” are obtained at the irradiation position C in reverse chronological order, and data to be interpolated are the current value and invalid data. For this purpose, data preceding by three rotations and two rotations that have values close to the valid data are interpolated by a straight line. Since a change during one rotation is 4.6−4.7=−0.1, the value next to 4.8 at the irradiation position C is 4.8−0.1=4.7, which is stored as an interpolated value.

The same processing is performed for data preceding by two rotations and one rotation in the first measurement system. Since 4.4−4.6=−0.2, −0.2 is subtracted from the previously calculated value “4.7”, and data is interpolated by 4.7−0.2=4.5.

In this way, an interpolated value is calculated along changes in average data at an irradiation position in a similar polishing progress state. Successive invalid data can be interpolated with higher precision than simple linear interpolation.

(Eighth Embodiment)

The eighth embodiment prevents erroneous detection or a failure in detecting the end point of polishing when, e.g., a wafer having only an insulating film before pattern formation is polished due to an operation error. The arrangement of this embodiment requires at least one measurement system described in the third embodiment.

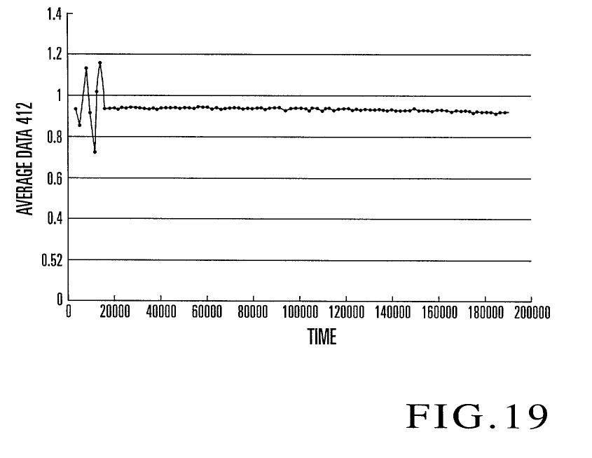

When a wafer 1 having an insulating film but no interconnection pattern is polished, the reflected light quantity increases or decreases much slowly than when a metal film 201 or barrier film 202 is polished. FIG. 19 shows a waveform when a wafer having only an insulating film 203 is polished. From this graph, the reflected light quantity changes as follows. Note that whether the reflected light quantity increases or decreases slowly is determined depending on the composition of an irradiation position and the wavelength of inspection light. In either case, the reflected light quantity changes slowly.

From this graph, a relatively large signal change appears at the beginning of polishing, and the reflected light quantity decreases very slowly. The relatively large signal change appears at the beginning of polishing until the wafer 1 and a polisher 2 adapt to each other, and is different from a change along with polishing progress in the initial unstable region. The reflected light quantity decreases very slowly owing to the influence of reflection by an underlying layer as the film becomes thinner along with polishing progress and transmits inspection light, or owing to interference of inspection light upon changes in film thickness.

In the algorithm C described in the third embodiment, erroneous detection may occur if a predetermined number of times is small in the condition “minimum value is not detected by a predetermined number of times” in the first process. Also, when an inclination calculation unit 413 is to calculate the average inclination of a plurality of data preceding by a predetermined number of data containing the current value among average data, but “the number of data preceding by a predetermined number of data” is small, inclination data slightly increases and decreases, and the algorithm may erroneously detect these changes. However, if such a predetermined number of data is set extremely large, the end point of polishing may be detected with a delay or may fail to be detected.

To prevent erroneous detection caused by small changes, no detection is performed when the reflected light quantity slowly decreases. If the end point of polishing cannot be detected even upon the lapse of a predetermined time, polishing forcibly ends.

A method of detecting whether the reflected light quantity slowly changes will be described. Average data initially obtained upon the lapse of a predetermined time is held because a relatively large signal change at the beginning of polishing is ignored. If average data obtained every rotation varies at a predetermined ratio or more in comparison with the held value, the first processes of all algorithms start. When the end point of polishing is detected at a plurality of irradiation positions, the first processes may be done at the respective irradiation positions, or variations in average data may be detected at a specific irradiation position to start algorithms at all the irradiation positions. Detection at respective irradiation positions enables detecting the end point of polishing even if a measurement system at a specific irradiation position exceeds the service life of a laser, or is damaged and cannot emit light.

As a forcible end method, when the lapse of time from the start of polishing exceeds a predetermined time, an alarm is output or detection of the end point of polishing is forcibly output to the apparatus. The predetermined time depends on the type of wafer 1, the thickness of the barrier film 202, the material of the barrier film 202, and the type of polishing solution. The predetermined time is slightly longer than the time taken to detect a definite change after the start of polishing in polishing a wafer requiring the longest polishing time, and is much shorter than the time taken to end polishing. This forcible end function can prevent the polisher 2 or polishing solution from being wastefully consumed by continuous polishing when the barrier film 202 is made of an unexpected material.

In detecting whether the reflected light quantity slowly changes, another predetermined time is set, the polishing time of a wafer requiring the longest polishing time is compared with the set time, and if the reflected light quantity does not vary at a predetermined ratio or more even upon the lapse of the polishing time of this wafer, polishing forcibly ends. Accordingly, wasteful consumption of the polisher 2 or polishing solution by continuous polishing can be minimized even when an unexpected situation occurs such that the polishing solution scatters to a lens or the like during wafer polishing, failing in measurement.

(Ninth Embodiment)

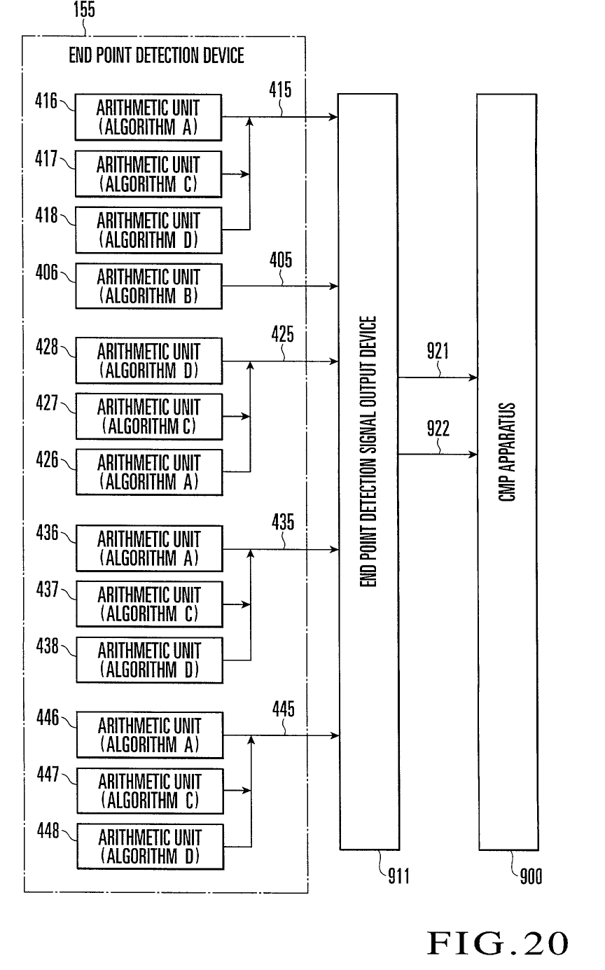

The ninth embodiment shown in FIG. 20 relates to a polishing end point detection apparatus for detecting the end point of polishing by using a plurality of measurement systems when a wafer has an in-plane distribution. The arrangement of the ninth embodiment can adopt infinite combinations of measurement systems. In this case, the arrangement shown in FIG. 15 (fifth embodiment) is employed.

In FIG. 20, the arrangement and operation up to output of end point detection signals 405, 415, 425, 435, and 445 are the same as those described in the first to eighth embodiments, and a description thereof will be omitted. An end point detection signal output device 911 receives the end point detection signals 405, 415, 425, 435, and 445, and outputs to a CMP apparatus 900 a polishing progress signal 922 converted into a data format which allows the CMP apparatus 900 to recognize a polishing distribution. At the same time, the end point detection signal output device 911 outputs a polishing end signal 921 to the CMP apparatus 900 at the end point of polishing determined by an arbitrarily selected polishing end condition.

The operation of the apparatus according to the ninth embodiment will be explained. An end point detection signal output from each measurement system represents the progress of an algorithm, as shown in Table 1 described in the seventh embodiment. The value of a reflected light quantity signal at the end point of polishing is almost constant even between measurement systems or even after the wafer 1 changes. However, if average data icreases, as described in the first embodiment, a signal at the same level as the reflected light quantity signal at the end point of polishing exists even during polishing. For this reason, the reflected light quantity signal is not suited to checking a polishing distribution. Hence, the end point detection signal should represent the progress of an algorithm, and details thereof will be described below though they have already been described in the seventh embodiment.

Polishing progress at the irradiation position A is represented by one of the end point detection signals 405, 415, and 425 that is output from a measurement system which most progresses. The end point detection signals 415 are output from arithmetic units 416, 417, and 418 which respectively execute the algorithms A, C, and D, and contain corresponding progress information.

A method of expressing the progress of the algorithm A will be first described. As shown in FIG. 6, the algorithm A is formed by two processes. Each algorithm is divided into a plurality of processes, and each process contains a conditional loop for satisfying a given condition in the process. Hence, process progress and condition progress will be separately considered. Process progress is expressed by “0/2” when no algorithm is executed, “1/2” when the algorithm is executed and the first process is being executed, and “2/2” when the second process is being executed. Process progress is “0” when no polishing or no algorithm is executed, and “1” when polishing enters the final step, which facilitates subsequence comparison.

Condition progress in the first process is expressed by “number of times of holding of condition (inclination data>threshold)/predetermined number of times” in a combination of “inclination data>threshold?” processing in step S102 of FIG. 6 and “exceed a predetermined number of times?” processing in step S103. For example, if a predetermined number of times is 5 and the condition “inclination data>threshold” holds twice, condition progress is expressed by “2/5”. Condition progress is “0” when no polishing or no algorithm is executed, and “1” when the condition is satisfied. Then, the process shifts to the next step. If both process progress and condition progress represent “1”, the end point of polishing is detected, and the polishing state can be determined from the process progress and condition progress.

Similar to the first process, condition progress in the second process is expressed by “current inclination data<number of times of holding of condition (maximum inclination data×predetermined magnification)/predetermined number of times” in a combination of “inclination data<number of “maximum inclination data×predetermined magnification?” processing in step S205 of FIG. 6 and “exceed a predetermined number of times?” processing in step S204. The arithmetic unit 416 which executes the algorithm A outputs two pieces of information, process progress and condition progress.

A method of expressing the progress of the algorithm C will be described. As shown in FIG. 13, the algorithm C is formed by four processes. Process progress is expressed by “0/4” when no algorithm is executed, “1/4” when the algorithm is executed and the first process is being executed, “2/4” when the second process is being executed, “3/4” when the third process is being executed, and “4/4” when the fourth process is being executed. Process progress is “0” when no polishing or no algorithm is executed, and “1” when polishing enters the fourth process as the final step, which facilitates subsequence comparison.

Condition progress in the first process is expressed by “current number of minimum point non-detection times/predetermined number of times” in the decision “minimum point not detected a predetermined number of times?” in step S107 of FIG. 13. The decision “minimum value=0 or more?” in step S108 where only whether to stop or execute the algorithm C is determined does not loop and does not influence condition progress.

Condition progress in the second process is expressed by “(minimum value×predetermined magnification/current inclination data” in the decision “inclination data≧minimum value×predetermined magnification?” in step S208 of FIG. 13. In the third process, condition progress is expressed by “lapse of time from intermediate time point/(lapse of time×predetermined magnification)” in the decision “lapse of time from intermediate time point≧lapse of time×predetermined magnification?” in step S301 of FIG. 13. In the fourth process, condition progress is expressed by “number of (inclination data≧predetermined threshold) times/predetermined number of times” in a combination of “inclination data≧predetermined threshold?” in step S401 of FIG. 13 and “condition satisfied a predetermined number of times?” in step S402. Similar to the algorithm A, the algorithm C outputs two pieces of information, process progress and condition progress.

A method of expressing the progress of the algorithm D will be described. As shown in FIG. 17, the algorithm D is formed by two processes. Process progress is expressed by “0/2” when no algorithm is executed, “1/2” when the algorithm is executed and the first process is being executed, and “2/2” when the second process is being executed. This facilitates subsequence comparison, as described in the algorithm A.

As for condition progress, the first process includes two conditional loops: the decision “algorithm C reach step 4?” in step S109 and the decision “end point detected at another irradiation position?” in step S110. For example, the decision of step S109 is looped until process progress meaning the fourth process, i.e., final step represents “1” in the progress of the algorithm C. In this case, the time point when the flow reaches the fourth process of the algorithm C may be quantitatively converted into “1”, but it is easier to simply obtain condition progress.

Since the first process includes two conditional loops, condition progress is expressed by “1/2” during the conditional loop of step S109 and “2/2” during the conditional loop of step S110.

Condition progress in the second process is expressed by “|average data—target value|/predetermined threshold” in the decision “|average data—target value|≦predetermined threshold?” in step S210 of FIG. 17. Similar to the algorithm A, the algorithm D outputs two pieces of information, process progress and condition progress.

The end point detection signal 415 in the first measurement system expresses pieces of process progress information and pieces of condition progress in the algorithms A, C, and D. Similarly, the end point detection signal 425 in the second measurement system, the end point detection signal 435 in the third measurement system, and the end point detection signal 445 in the fourth measurement system express pieces of process progress information and pieces of condition progress.

The algorithm B is formed by two processes, as shown in FIG. 10, and the progress of the algorithm B is expressed by “0/2” when no algorithm is executed, “1/2” when the algorithm is executed and the first process is being executed, and “2/2” when the second process is being executed. Process progress is “0” when no polishing or no algorithm is executed, and “1” when polishing enters the final step, which facilitates subsequence comparison.

Condition progress in the first process is expressed by “current number of successive condition satisfaction times/predetermined number of times” in a combination of “absolute value of difference inclination increase?” in step S104 of FIG. 10 and “condition successively satisfied a predetermined number of times?” in step S105. Condition progress in the second process is expressed by “current total number of times of holding of condition (predetermined threshold or less)/predetermined number of times” in a combination of “difference inclination data≦predetermined threshold?” in step S205 of FIG. 10 and “condition satisfied a predetermined number of times as a whole?” in step S206. Similar to the remaining algorithms, the algorithm B outputs two pieces of information, process progress and condition progress.

To express polishing progress at the irradiation position A, pieces of process progress information and pieces of condition progress information that are respectively obtained by the algorithms A, C, and D and contained in the end point detection signals 415 are compared. In this comparison, whether both process progress and condition progress exhibit values close to 1 is checked, and the progress of an algorithm represents polishing progress obtained from a corresponding end point detection signal 415.

In comparison, condition progress is reset every time the process changes, so an algorithm in which the sum of process progress and condition progress is close to “2” should not be determined as an algorithm which most progresses. If two or more algorithms which most progress are found by comparing pieces of process progress information, pieces of condition progress information are compared and determined as progress in an end point detection signal, or are weighted and compared.

As a weighting example, process progress is multiplied by 10, the product is added to condition progress, sums obtained in this manner are compared between algorithms, and the progress of an algorithm exhibiting a value closest to “11” or the largest value is adopted as the end point detection signal 415.

Accordingly, pieces of progress information in the end point detection signals 405, 415, 425, 435, and 445 can be obtained. Progress at each irradiation position can be obtained by comparison similar to comparison of progress for each algorithm by an end point detection signal.

At the irradiation position A, the end point detection signals 405, 415, and 425 are compared, and a signal which most progresses represents progress at the irradiation position A. Progress at the irradiation position B is represented by the end point detection signal 435, and progress at the irradiation position C is represented by the end point detection signal 445. The end point detection signals are output as the polishing progress signals 922. Polishing progress states at all irradiation positions exhibit a polishing distribution on the polished wafer surface.

To polish a wafer so as to reduce the wafer in-plane distribution, if the CMP apparatus 900 has a comparison function similar to algorithm progress comparison, the CMP apparatus 900 compares progress states by using the polishing progress signals 922 as pieces of progress information at all irradiation positions, and mainly polishes a wafer portion where polishing most delays. If the CMP apparatus 900 does not have any comparison function, the end point detection signal output device 911 compares progress states at irradiation positions, and outputs as the polishing progress signal 922 an irradiation position where polishing delays or progresses. In this case, the CMP apparatus 900 mainly polishes a portion where polishing delays in accordance with the polishing progress signal 922, and hardly polishes a portion where polishing progresses, thus reducing the polishing distribution on the polished wafer surface.

A method of ending polishing by detecting the end point of polishing at an arbitrary point on a wafer surface will be described. Similar to algorithm progress comparison, the end point detection signal output device 911 compares progress states at all irradiation positions, and when detecting the end point of polishing at one or a plurality of arbitrarily selectable irradiation positions, outputs the polishing end signal 921. The CMP apparatus 900 receives the polishing end signal 921 and ends polishing operation. This method is effective particularly when a portion difficult to polish is obtained in advance.

When polishing is influenced by an in-plane distribution in the preceding step or an in-plane distribution by polishing nonuniformity exists, a satisfactorily polished portion, excessively polished portion, and insufficiently polished portion coexist on one wafer. In this case, the yield may greatly change depending on the ratio of these portions. To solve this, the time taken until the end point of polishing is detected is held in place of detecting the end point of polishing at one or a plurality of arbitrarily selectable irradiation positions. If the end point of polishing cannot be detected at one or a plurality of arbitrarily selectable irradiation positions even upon the lapse of a predetermined time, the end point detection signal output device 911 forcibly outputs a polishing end point detection signal.

This can minimize excessive polishing at a portion where polishing is first completed, and can stabilize the yield.

As has been described above, according to the present invention, removal of a barrier film from an insulating film can be detected as the end point of polishing at high precision.

The surface of a semiconductor wafer suffers nonuniformity of polishing itself or polishing nonuniformity caused by variations in film thickness in the preceding film formation step before polishing. It is difficult to make the surface uniform. According to the present invention, polishing can be ended by measuring the distribution of polishing progress states on a wafer surface with a plurality of measurement systems, and detecting the end point of polishing at an arbitrary position on the polished wafer surface. Further, the end point of polishing can be properly changed based on the polishing distribution on the surface of a semiconductor wafer such that polishing ends when polishing end point detection at a portion where polishing most delays is done. To obtain an optimal polishing result or reduce polishing nonuniformity, the CMP apparatus can be informed of wafer polishing distribution information.

When two or more types of measurement operations are done at a certain measurement point, the measurement data can be exploited to determine the end point of polishing at another measurement point. That is, measurement data at the same polishing progress degree is the same between measurement points for each measurement method, and another measurement point suffices to receive a smaller number of types of measurement operations. In this case, the number of measurement types can be decreased by estimating types of measurement values not obtained by actual measurement from the same types of measurement values, unlike many types of measurement points. Moreover, the degree of polishing nonuniformity can be confirmed during polishing by detecting the end point of polishing at each point on a wafer surface with a plurality of measurement systems and displaying the polishing progress degree during polishing.

As has been described above, according to the present invention, removal of a barrier film from an insulating film except for a metal film and barrier film at an interconnection portion is detected, so that the final end point of polishing can be detected with high precision on a semiconductor wafer from which a metal film is removed except for an interconnection portion but no barrier film is removed. Polishing can be ended by detecting the end point of polishing at an arbitrary position on a wafer surface or determining the end point of polishing on the basis of a combination of polishing states at respective points.

By arranging a plurality of measurement systems, the end point of polishing is detected at the respective points, and a rough polishing progress degree is obtained from the decision status of a polishing end point determination algorithm. The polishing progress degree at each point can be measured and informed to the CMP apparatus. If the CMP apparatus has a function of controlling the apparatus in order to reduce polishing nonuniformity on the CMP apparatus side, information can be fed back to the CMP apparatus during polishing so as to reduce polishing nonuniformity.

Measurement data is the same even between different measurement positions on a single wafer as far as the polishing progress degree is the same. A plurality of measurement systems are arranged to estimate and interpolate data from a measurement system exhibiting a similar polishing progress degree. Even if part of the optical axis of a measurement system is shielded by swings of a pad, data obtained when part of the optical axis is shielded can be interpolated so long as measurement data can be acquired to some extent.

What is claimed is:

1. A semiconductor wafer polishing end point detection method comprising the steps of:
measuring, by using at least one measurement system, a polishing progress state distribution on a surface of a semiconductor wafer by chemical and mechanical polishing in forming a metal wire; and
detecting an end point of polishing on the basis of a measurement result, thereby obtaining an optimal polishing result.

2. A method according to claim 1, wherein the measurement step comprises the steps of
irradiating an irradiation position on the surface of the semiconductor wafer at a predetermined diameter with inspection light having a predetermined wavelength from a light source constituting the measurement system, and
receiving, by a light-receiving element constituting the measurement system, the inspection light from the light source that is reflected by the surface of the semiconductor wafer.

3. A method according to claim 2, wherein the step of detecting the end point of polishing comprises the steps of
obtaining average data of a reflected light quantity for one rotation of the semiconductor wafer that is attained from the light-receiving element,
calculating, from the obtained average data, inclination data representing an average inclination of a plurality of average data that contain a current value and correspond to a predetermined number of immediately preceding rotations of the semiconductor wafer, and
detecting, from the calculated inclination data, that the average data stabilizes after an increase in the average data, thereby determining the end point of polishing.

4. A method according to claim 3, wherein the step of detecting the end point of polishing comprises the steps of
setting in advance a threshold around “0” in order to detect whether the inclination data is a positive value,
comparing the inclination data with the threshold to determine whether the inclination data is larger than the threshold, and
determining an increase in the average data when the inclination data successively exceeds the threshold a predetermined number of times.

5. A method according to claim 3, wherein the step of detecting the end point of polishing comprises the steps of
checking the inclination data to hold a maximum value of the inclination data, and
detecting the end point of polishing when the inclination data satisfies a predetermined number of times a condition that the inclination data is smaller than a value obtained by multiplying the held maximum value of the inclination data by a predetermined magnification.

6. A method according to claim 1, further comprising the steps of:
performing at least one measurement at one measurement point; and
estimating an end point of polishing at another measurement point by using measurement data for determining the end point of polishing at the other measurement point.

7. A method according to claim 1, further comprising the step of displaying a polishing progress degree on the basis of the measurement result during polishing of the semiconductor wafer.

8. A semiconductor wafer polishing end point detection method comprising the steps of:
detecting, by using at least one measurement system, an end point of polishing on at least one measurement point on a surface of a semiconductor wafer having an interconnection metal film serving as an upper layer covering an insulating film serving as a lower layer and a barrier film formed between the metal film and the insulating film to prevent diffusion of the metal film after the barrier film on the metal film is removed;
displaying a polishing progress degree during polishing of the semiconductor wafer; and
obtaining an optimal polishing result on the basis of the displayed polishing progress degree.

9. A method according to claim 8, wherein the step of detecting the end point of polishing comprises the steps of
detecting the end point of polishing by measuring a reflected light quantity at at least one measurement point on the surface of the semiconductor wafer with an optical measurement system, and
forcibly ending polishing when the reflected light quantity gradually decreases, the decrease is not detected as the end point of polishing, and the end point of polishing cannot be detected even upon a lapse of a predetermined time after start of polishing.

10. A method according to claim 8, wherein the step of detecting the end point of polishing comprises the steps of
obtaining and holding average data of reflected light quantities for one rotation of the semiconductor wafer,
comparing average data obtained every rotation of the semiconductor wafer with the held average data, and
detecting the end point of polishing only when a comparison result exhibits variations in average data at not less than a predetermined ratio.

11. A semiconductor wafer polishing end point detection apparatus comprising:
first measurement means for optically measuring a polishing progress state distribution on a surface of a semiconductor wafer by chemical and mechanical polishing in forming a metal wire, said first measurement means having a light source for irradiating an irradiation position on the surface of the semiconductor wafer at a predetermined diameter with inspection light having a predetermined wavelength, and a light-receiving element for receiving the inspection light from said light source that is reflected by the surface of the semiconductor wafer; and
end point detection means for detecting an end point of polishing on the basis of a measurement result output from said first measurement means, thereby obtaining an optimal polishing result.

12. An apparatus according to claim 11, wherein said end point detection means comprises
an average calculation unit for obtaining average data of reflected light quantities for one rotation of the semiconductor wafer that are attained from said light source of said first measurement means,
an inclination calculation unit for calculating, from the average data output from said average calculation unit, inclination data representing an average inclination of a plurality of average data that contain a current value and correspond to a predetermined number of immediately preceding rotations of the semiconductor wafer, and
an arithmetic unit for detecting that the average data stabilizes after an increase in the average data, on the basis of the inclination data output from said inclination calculation unit, thereby determining the end point of polishing.

13. An apparatus according to claim 11, wherein said apparatus further comprises
a light source for irradiating the irradiation position on the surface of the semiconductor wafer with inspection light at the same diameter but a predetermined irradiation angle and predetermined wavelength different from an irradiation angle and wavelength of said light source of said first measurement system, and
a second measurement system having a light-receiving element for receiving the inspection light from said light source that is reflected by the surface of the semiconductor wafer, and
said end point detection means comprises
a difference calculation unit for calculating difference data representing a difference between average data of respective reflected light quantities obtained from said light-receiving elements of said first and second measurement systems,
a difference inclination calculation unit for calculating difference inclination data representing an average inclination at a plurality of points in the difference data output from said difference calculation unit, and
a first arithmetic unit for detecting the end point of polishing on the basis of a temporal change in the difference inclination data output from said difference inclination calculation unit.

14. An apparatus according to claim 13, wherein said first arithmetic unit uses a value for determining vicinity of “0” as an end point determination threshold and determines the end point of polishing when an absolute value of the difference inclination data successively falls within the end point determination threshold not less than a predetermined number of times, when the absolute value of the difference inclination data falls within the end point determination threshold not less than a predetermined number of times as a whole after the absolute value reaches not less than a predetermined value, and when a ratio at which the difference inclination data falls within the end point determination threshold reaches not less than a predetermined ratio.

15. An apparatus according to claim 13, wherein said end point detection means further comprises
a first average calculation unit for obtaining average data of reflected light quantities for one rotation of the semiconductor wafer that are attained from said light-receiving elements of said first measurement means,
a first inclination calculation unit for calculating, from the average data output from said first average calculation unit, inclination data representing an average inclination of a plurality of average data that contain a current value and correspond to a predetermined number of immediately preceding rotations of the semiconductor wafer,
a second arithmetic unit for detecting that the average data stabilizes after an increase in the average data, on the basis of the inclination data output from said first inclination calculation unit, thereby determining the end point of polishing,
a second average calculation unit for obtaining average data of reflected light quantities for one rotation of the semiconductor wafer that are attained from said light-receiving elements of said second measurement means,
a second inclination calculation unit for calculating, from the average data output from said second average calculation unit, inclination data representing an average inclination of a plurality of average data that contain a current value and correspond to a predetermined number of immediately preceding rotations of the semiconductor wafer, and
a third arithmetic unit for detecting that the average data stabilizes after an increase in the average data, on the basis of the inclination data output from said second inclination calculation unit, thereby determining the end point of polishing.
